(19) United States
(12) Patent Application Publication
(10) Pub. No.: US 2024/0339317 A1
(43) Pub. Date: Oct. 10, 2024

(54) SUBSTRATE TREATING METHOD AND TREATMENT LIQUID

(71) Applicant: SCREEN Holdings Co., Ltd., Kyoto (JP)

(72) Inventors: Shogo KUNIEDA, Kyoto (JP); Yuta SASAKI, Kyoto (JP)

(21) Appl. No.: 18/551,302

(22) PCT Filed: Jan. 20, 2022
(86) PCT No.: PCT/JP2022/001980

§ 371 Date: Sep. 19, 2023

(30) Foreign Application Priority Data
Mar. 24, 2021 (JP) 2021-050137

(51) Int. Cl. H01L 21/02; B05D 3/04

(52) U.S. Cl. CPC H01L 21/02282; B05D 3/0406; B05D 3/0466; B05D 2320/10; B05D 2401/10

(57) ABSTRACT

This disclosure relates to a substrate treating method and a treatment liquid. The substrate treating method includes a treatment liquid supplying step, a solidified film forming step, and a sublimation step. In the treatment liquid supplying step, a treatment liquid is supplied to a substrate. The treatment liquid contains a sublimable substance, a solvent, and a surfactant. In the solidified film forming step, the solvent and the surfactant evaporate from the treatment liquid on the substrate. In the solidified film forming step, a solidified film containing the sublimable substance is formed on the substrate. In the sublimation step, the solidified film sublimates. The surfactant has an octanol-water partition coefficient LOGPow of −1 or more and 1 or less. Vapor pressure Pc of the surfactant at room temperature is 0.9 times or more and 3 times or less vapor pressure Pb of the solvent at room temperature.

### TECHNICAL FIELD

The present invention relates to a substrate treating method for performing treatment on substrates and a treatment liquid used for drying the substrates. Examples of the substrates include a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, and a solar cell substrate.

### BACKGROUND ART

Patent Literature 1 discloses a substrate treating method for drying substrates. Specifically, the substrate treating method disclosed in Patent Literature 1 includes a treatment liquid supplying step, a solidified film forming step, and a sublimation step. In the treatment liquid supplying step, a treatment liquid is supplied to the substrates. The treatment liquid contains a solvent, a sublimable substance, and an adsorbent substance. The adsorbent substance is, for example, a surfactant. In the solidified film forming step, the solvent evaporates. In the solidified film forming step, a solidified film of the sublimable substance is formed on the substrate. In the sublimation step, the solidified film sublimates. The solidified film changes into gas without being a liquid.

### PRIOR ART DOCUMENT

### Patent Literature

### [Patent Literature 1]

Japanese Unexamined Patent Publication No. 2020-4948A

### SUMMARY OF INVENTION

### Technical Problem

Even with the currently-used substrate treating method, a substrate may not be dried appropriately occasionally. For example, even with the currently-used substrate treating method, a pattern formed on a surface of a substrate may collapse. For example, if a pattern is fine, the currently-used substrate treating method may insufficiently suppress collapse of the pattern.

The present invention has been made regarding the state of the art noted above, and its one object is to provide a substrate treating method and a treatment liquid that can dry substrates appropriately.

### Solution to Problem

To overcome the above drawbacks, Inventors herein have made intensive research. Firstly, the Inventors studied a reason why a substrate cannot be dried appropriately. Then, the Inventors made a guess that failure to appropriately dry the substrate is caused by a treatment liquid used for drying the substrate. For example, the Inventors made a guess that failure to appropriately dry the substrate is caused by selection of a sublimable substance, a solvent, and a surfactant. Then, the Inventors searched a more suitable treatment liquid. The Inventors searched a condition to be satisfied with the treatment liquid.

The present invention has been made based on the above finding through further studious consideration, and thus is constituted as stated below. One aspect of the present invention provides a substrate treating method for performing treatment on a substrate. The substrate treating method includes: a treatment liquid supplying step of supplying a treatment liquid, containing a sublimable substance, a solvent, and a surfactant, to the substrate; a solidified film forming step of forming a solidified film containing the sublimable substance on the substrate by evaporating the solvent and the surfactant from the treatment liquid on the substrate; and a sublimation step of sublimating the solidified film. The surfactant has an octanol-water partition coefficient of −1 or more and 1 or less, and vapor pressure of the surfactant at room temperature is 0.9 times or more and 3 times or less vapor pressure of the solvent at room temperature.

The substrate treating method includes the treatment liquid supplying step, the solidified film forming step, and the sublimation step. In the treatment liquid supplying step, the treatment liquid is supplied to the substrates. The treatment liquid contains the sublimable substance, the solvent, and the surfactant. In the solidified film forming step, the solvent and the surfactant evaporate from the treatment liquid on the substrate. In the solidified film forming step, the solidified film is formed on the substrate. The solidified film contains the sublimable substance.

In the sublimation step, the solidified film sublimates.

The treatment liquid satisfies a first condition.

First Condition: The surfactant has an octanol-water partition coefficient of −1 or more and 1 or less.

Accordingly, the treatment liquid has suitable affinity to the substrate. As a result, the treatment liquid can be supplied suitably to the substrate in the treatment liquid supplying step.

The treatment liquid satisfies a second condition.

Second Condition: Vapor pressure of the surfactant at room temperature is 0.9 times or more vapor pressure of the solvent at room temperature, and 3 times or less vapor pressure of the solvent at room temperature.

Vapor pressure of the surfactant at room temperature is 3 times or less vapor pressure of the solvent at room temperature. Accordingly, vapor pressure of the surfactant at room temperature is not excessively high. As a result, the treatment liquid can be supplied more suitably to the substrate in the treatment liquid supplying step.

In addition, vapor pressure of the surfactant at room temperature is 0.9 times or more vapor pressure of the solvent at room temperature. Consequently, vapor pressure of the surfactant at room temperature is not excessively low. As a result, the surfactant evaporates suitably in the solidified film forming step. Since the surfactant evaporates suitably, the sublimable substance is deposited suitably. As a result, the solidified film can be formed on the substrate appropriately in the solidified film forming step.

In summary, since the treatment liquid satisfies the first condition and the second condition, the treatment liquid can be supplied suitably to the substrate in the treatment liquid supplying step. Since the treatment liquid satisfies the second condition, the solidified film can be formed on the substrate appropriately in the solidified film forming step. As a result, the substrate treating method described above achieves proper drying of substrates.

It is preferred in the substrate treating method described above that the vapor pressure of the solvent at room temperature is higher than vapor pressure of the sublimable substance at room temperature.

The treatment liquid satisfies a third condition.

Third Condition: Vapor pressure of the solvent at room temperature is higher than vapor pressure of the sublimable substance at room temperature.

Accordingly, the solvent evaporates more easily than the sublimable substance. Since the solvent evaporates, the sublimable substance is deposited more suitably. As a result, the solidified film can be formed on the substrate more suitably in the solidified film forming step.

It is preferred in the substrate treating method described above that the vapor pressure of the surfactant at room temperature is higher than vapor pressure of the sublimable substance at room temperature.

The treatment liquid satisfies a fourth condition.

Fourth Condition: Vapor pressure of the surfactant at room temperature is higher than vapor pressure of the sublimable substance at room temperature.

Accordingly, the surfactant evaporates more easily than the sublimable substance. Since the surfactant evaporates, the sublimable substance is deposited more suitably. As a result, the solidified film can be formed on the substrate more suitably in the solidified film forming step.

It is preferred in the substrate treating method described above that the sublimable substance is one selected from cyclohexanone oxime, camphor, and ε-caprolactam, and that the solvent and the surfactant correspond to one selected from the following features a1) to a20):
a1) the solvent is methanol, and the surfactant is acetone;
a2) the solvent is ethanol, and the surfactant is methanol;
a3) the solvent is isopropyl alcohol, and the surfactant is methanol;
a4) the solvent is isopropyl alcohol, and the surfactant is ethanol;
a5) the solvent is isopropyl alcohol, and the surfactant is tert-butanol;
a6) the solvent is tert-butanol, and the surfactant is methanol;
a7) the solvent is tert-butanol, and the surfactant is ethanol;
a8) the solvent is tert-butanol, and the surfactant is isopropyl alcohol;
a9) the solvent is 1-propanol, and the surfactant is ethanol;
a10) the solvent is 1-propanol, and the surfactant is isopropyl alcohol;
a11) the solvent is 1-propanol, and the surfactant is tert-butanol;
a12) the solvent is isobutanol, and the surfactant is 1-propanol;
a13) the solvent is 1-ethoxy-2-propanol, and the surfactant is 1-propanol;
a14) the solvent is 1-ethoxy-2-propanol, and the surfactant is isobutanol;
a15) the solvent is 1-butanol, and the surfactant is 1-propanol;
a16) the solvent is 1-butanol, and the surfactant is isobutanol;
a17) the solvent is 1-butanol, and the surfactant is 1-ethoxy-2-propanol;
a18) the solvent is propylene glycol monomethyl ether acetate, and the surfactant is isobutanol;
a19) the solvent is propylene glycol monomethyl ether acetate, and the surfactant is 1-ethoxy-2-propanol; and
a20) the solvent is propylene glycol monomethyl ether acetate, and the surfactant is 1-butanol.

The treatment liquid satisfies the first condition and the second condition suitably when the sublimable substance, the solvent and the surfactant are specified as above. Accordingly, the substrate treating method can dry the substrates suitably.

It is preferred in the substrate treating method described above that the substrate has a pattern formed on a surface of the substrate. With the substrate treating method, the substrate having the pattern can be dried suitably while the pattern is protected.

Another aspect of the present invention provides a treatment liquid used for drying the substrates. The treatment liquid contains a sublimable substance, a solvent, and a surfactant. The surfactant has an octanol-water partition coefficient of −1 or more and 1 or less, and vapor pressure of the surfactant at room temperature is 0.9 times or more and 3 times or less vapor pressure of the solvent at room temperature.

The treatment liquid is used to dry the substrates. The treatment liquid contains the sublimable substance, the solvent, and the surfactant.

The treatment liquid satisfies the first condition described above. Specifically, the surfactant has an octanol-water partition coefficient of −1 or more and 1 or less. Accordingly, the treatment liquid has suitable affinity to the substrate. Consequently, when the treatment liquid is supplied to a substrate, for example, the treatment liquid satisfactorily contacts the substrate.

The treatment liquid satisfies the second condition described above. Specifically, vapor pressure of the surfactant at room temperature is 0.9 times or more and 3 times or less vapor pressure of the solvent at room temperature. Accordingly, vapor pressure of the surfactant at room temperature is not excessively high. Consequently, when the treatment liquid is supplied to a substrate, for example, the treatment liquid satisfactorily and certainly contacts the substrate. Moreover, vapor pressure of the surfactant at room temperature is not excessively low. As a result, the surfactant evaporates suitably. Since the surfactant evaporates suitably, the sublimable substance is deposited suitably, and the solidified film is formed suitably.

As described above, the treatment liquid satisfies the first condition and the second condition. As a result, the treatment liquid achieves suitable drying of the substrates.

It is preferred in the treatment liquid described above that vapor pressure of the solvent at room temperature is higher than vapor pressure of the sublimable substance at room temperature. The treatment liquid satisfies the third condition described above. Accordingly, the solvent evaporates more easily than the sublimable substance. Since the solvent evaporates, the sublimable substance is deposited more suitably, and the solidified film is formed more suitably.

It is preferred in the treatment liquid described above that vapor pressure of the surfactant at room temperature is higher than vapor pressure of the sublimable substance at room temperature. The treatment liquid satisfies the fourth condition described above. Accordingly, the surfactant evaporates more easily than the sublimable substance. Since the surfactant evaporates, the sublimable substance is deposited more suitably, and the solidified film is formed more suitably.

It is preferred in the treatment liquid described above that the sublimable substance corresponds to one selected from cyclohexanone oxime, camphor, and ε-caprolactam, and that the solvent and the surfactant correspond to one selected from the following features a1) to a20):
a1) the solvent is methanol, and the surfactant is acetone;
a2) the solvent is ethanol, and the surfactant is methanol;
a3) the solvent is isopropyl alcohol, and the surfactant is methanol;
a4) the solvent is isopropyl alcohol, and the surfactant is ethanol;
a5) the solvent is isopropyl alcohol, and the surfactant is tert-butanol;
a6) the solvent is tert-butanol, and the surfactant is methanol;
a7) the solvent is tert-butanol, and the surfactant is ethanol;
a8) the solvent is tert-butanol, and the surfactant is isopropyl alcohol;
a9) the solvent is 1-propanol, and the surfactant is ethanol;
a10) the solvent is 1-propanol, and the surfactant is isopropyl alcohol;
a11) the solvent is 1-propanol, and the surfactant is tert-butanol;
a12) the solvent is isobutanol, and the surfactant is 1-propanol;
a13) the solvent is 1-ethoxy-2-propanol, and the surfactant is 1-propanol;
a14) the solvent is 1-ethoxy-2-propanol, and the surfactant is isobutanol;
a15) the solvent is 1-butanol, and the surfactant is 1-propanol;
a16) the solvent is 1-butanol, and the surfactant is isobutanol;
a17) the solvent is 1-butanol, and the surfactant is 1-ethoxy-2-propanol;
a18) the solvent is propylene glycol monomethyl ether acetate, and the surfactant is isobutanol;
a19) the solvent is propylene glycol monomethyl ether acetate, and the surfactant is 1-ethoxy-2-propanol; and
a20) the solvent is propylene glycol monomethyl ether acetate, and the surfactant is 1-butanol.

The treatment liquid satisfies the first condition and the second condition suitably when the sublimable substance, the solvent and the surfactant are specified as above. Consequently, a substrate can be dried suitably with use of the treatment liquid.

It is preferred in the treatment liquid described above that the sublimable substance corresponds to at least one selected from cyclohexanone oxime, camphor, and ε-caprolactam, and that the solvent and the surfactant correspond to one selected from the following features b1) to b9):
b1) the solvent is methanol, and the surfactant is acetone;
b2) the solvent is ethanol, and the surfactant is methanol;
b3) the solvent is isopropyl alcohol, and the surfactant is at least one selected from methanol, ethanol, and tert-butanol;
b4) the solvent is tert-butanol, and the surfactant is at least one selected from methanol, ethanol, and isopropyl alcohol;
b5) the solvent is 1-propanol, and the surfactant is at least one selected from ethanol, isopropyl alcohol, and tert-butanol;
b6) the solvent is isobutanol, and the surfactant is 1-propanol;
b7) the solvent is 1-ethoxy-2-propanol, and the surfactant is at least either 1-propanol or isobutanol;
b8) the solvent is 1-butanol, and the surfactant is at least one selected from 1-propanol, isobutanol, and 1-ethoxy-2-propanol; and
b9) the solvent is propylene glycol monomethyl ether acetate, and the surfactant is at least one selected from isobutanol, 1-ethoxy-2-propanol, and 1-butanol.

The treatment liquid satisfies the first condition and the second condition suitably when the sublimable substance, the solvent and the surfactant are specified as above. Consequently, a substrate can be dried suitably with use of the treatment liquid.

It is preferred in the treatment liquid described above that the sublimable substance corresponds to at least one selected from cyclohexanone oxime, camphor, and ε-caprolactam, and that the solvent and the surfactant correspond to one selected from the following features c1) to c9):
c1) the solvent is methanol, and the surfactant is acetone;
c2) the solvent is at least one selected from ethanol, isopropyl alcohol, and tert-butanol, and the surfactant is methanol;
c3) the solvent is at least one selected from isopropyl alcohol, tert-butanol, and 1-propanol, and the surfactant is ethanol;
c4) the solvent is at least either isopropyl alcohol or 1-propanol, and the surfactant is tert-butanol;
c5) the solvent is at least either tert-butanol or 1-propanol, and the surfactant is isopropyl alcohol;
c6) the solvent is at least one selected from isobutanol, 1-ethoxy-2-propanol, and 1-butanol, and the surfactant is 1-propanol;
c7) the solvent is at least one selected from 1-ethoxy-2-propanol, 1-butanol, and propylene glycol monomethyl ether acetate, and the surfactant is isobutanol;
c8) the solvent is at least either 1-butanol or propylene glycol monomethyl ether acetate, and the surfactant is 1-ethoxy-2-propanol; and
c9) the solvent is propylene glycol monomethyl ether acetate, and the surfactant is 1-butanol.

The treatment liquid satisfies the first condition and the second condition suitably when the sublimable substance, the solvent and the surfactant are specified as above. Consequently, a substrate can be dried suitably with use of the treatment liquid.

It is preferred in the treatment liquid described above that a volume of the sublimable substance contained in the treatment liquid is smaller than a volume of the solvent contained in the treatment liquid. A substrate can be dried more suitably with use of the treatment liquid.

It is preferred in the treatment liquid described above that a volume of the sublimable substance contained in the treatment liquid is 1% or more of a volume of the solvent contained in the treatment liquid. It is preferred in the treatment liquid described above that a volume of the sublimable substance contained in the treatment liquid is 10% or less of a volume of the solvent contained in the treatment liquid. A substrate can be dried more suitably with use of the treatment liquid.

It is preferred in the treatment liquid described above that a volume of the surfactant contained in the treatment liquid is smaller than a volume of the solvent contained in the treatment liquid. A substrate can be dried more suitably with use of the treatment liquid.

It is preferred in the treatment liquid described above that a volume of the surfactant contained in the treatment liquid is 0.01% or more of a volume of the solvent contained in the treatment liquid. It is preferred in the treatment liquid described above that a volume of the surfactant contained in the treatment liquid is 10% or less of a volume of the solvent contained in the treatment liquid. A substrate can be dried more suitably with use of the treatment liquid.

Another aspect of the present invention provides a substrate treating apparatus for treating a substrate. The substrate treating apparatus includes: a substrate holder configured to hold the substrate; a treatment liquid generating unit configured to generate a treatment liquid containing a sublimable substance, a solvent, and a surfactant, and a treatment liquid supplying unit configured to supply the treatment liquid to the substrate held by the substrate holder. The surfactant has an octanol-water partition coefficient of −1 or more and 1 or less, and vapor pressure of the surfactant at room temperature is 0.9 times or more and 3 times or less vapor pressure of the solvent at room temperature.

The substrate treating apparatus includes the substrate holder, the treatment liquid generating unit, and the treatment liquid supplying unit. The substrate holder holds a substrate. The treatment liquid generating unit generates the treatment liquid. The treatment liquid contains the sublimable substance, the solvent, and the surfactant. The treatment liquid supplying unit supplies the treatment liquid to the substrate held by the substrate holder. The treatment liquid supplying unit supplies the treatment liquid, generated by the treatment liquid generating unit, to the substrate held by the substrate holder.

Here, the treatment liquid generated by the treatment liquid generating unit satisfies the first condition and the second condition described above. Consequently, the substrate treating apparatus can perform the substrate treating method described above suitably. That is, the substrate treating apparatus can dry substrates appropriately.

It is preferred in the substrate treating apparatus described above that vapor pressure of the solvent at room temperature is higher than vapor pressure of the sublimable substance at room temperature. The treatment liquid generated by the treatment liquid generating unit satisfies the third condition described above. Accordingly, the substrate treating apparatus can dry the substrates more suitably.

It is preferred in the substrate treating apparatus described above that vapor pressure of the surfactant at room temperature is higher than vapor pressure of the sublimable substance at room temperature. The treatment liquid generated by the treatment liquid generating unit satisfies the fourth condition described above. Accordingly, the substrate treating apparatus can dry the substrates more suitably.

It is preferred in the substrate treating apparatus described above that the substrate held by the substrate holder has a pattern formed on the surface of the substrate. With the substrate treating apparatus, the substrate having the pattern can be dried suitably while the pattern is protected.

It is preferred that the substrate treating apparatus described above further includes a gas supplying unit configured to supply gas to the substrate held by the substrate holder. This can dry the substrate effectively.

### Advantageous Effects of Invention

The substrates can be dried suitably with the substrate treating method and the treatment liquid according to the present invention.

### BRIEF DESCRIPTION OF DRAWINGS

FIG. 1 is a plan view of an interior of a substrate treating apparatus according to a first embodiment.

FIG. 2 is a control block diagram of the substrate treating apparatus.

FIG. 3 shows a construction of a treating unit and a treatment liquid generating unit according to the first embodiment.

FIG. 4 is a table exemplarily illustrating a sublimable substance, a solvent, and a surfactant contained in a treatment liquid.

FIG. 5 is a table exemplarily illustrating a sublimable substance, a solvent, and a surfactant contained in the treatment liquid.

FIG. 6 is a table exemplarily illustrating a sublimable substance, a solvent, and a surfactant contained in the treatment liquid.

FIG. 7 is a table exemplarily illustrating a sublimable substance, a solvent, and a surfactant contained in the treatment liquid.

FIG. 8 is a table exemplarily illustrating a sublimable substance, a solvent, and a surfactant contained in the treatment liquid.

FIG. 9 is a table exemplarily illustrating a sublimable substance, a solvent, and a surfactant contained in the treatment liquid.

FIG. 10 is a table exemplarily illustrating a sublimable substance, a solvent, and a surfactant contained in the treatment liquid.

FIG. 11 is a table exemplarily illustrating a sublimable substance, a solvent, and a surfactant contained in the treatment liquid.

FIG. 12 is a flow chart showing procedures of a substrate treating method.

FIG. 13 schematically shows a substrate in a treatment liquid supplying step.

FIG. 14 schematically shows the substrate in a solidified film forming step.

FIG. 15 schematically shows the substrate in the solidified film forming step.

FIG. 16 schematically shows the substrate in a sublimation step.

FIG. 17 schematically shows the substrate in the sublimation step.

FIG. 18 is a table showing evaluations of substrates treated in first and second experimental examples and first to third comparative examples.

FIG. 19 exemplarily shows a mechanism for pattern collapse.

FIG. 20 exemplarily shows the mechanism for pattern collapse.

FIG. 21 exemplarily shows the mechanism for pattern collapse.

FIG. 22 exemplarily shows the mechanism for pattern collapse.

FIG. 23 exemplarily shows the mechanism for pattern collapse.

FIG. 24 exemplarily shows the mechanism for pattern collapse.

FIG. 25 exemplarily shows the mechanism for pattern collapse.

FIG. 26 exemplarily shows the mechanism for pattern collapse.

FIG. 27 shows a construction of a treating unit and a treatment liquid generating unit according to a second embodiment.

### DESCRIPTION OF EMBODIMENTS

The following describes a substrate treating method, a treatment liquid, and a substrate treating apparatus of the present invention with reference to the drawings.

### 1. First Embodiment

### <1-1. Outline of Substrate Treating Apparatus>

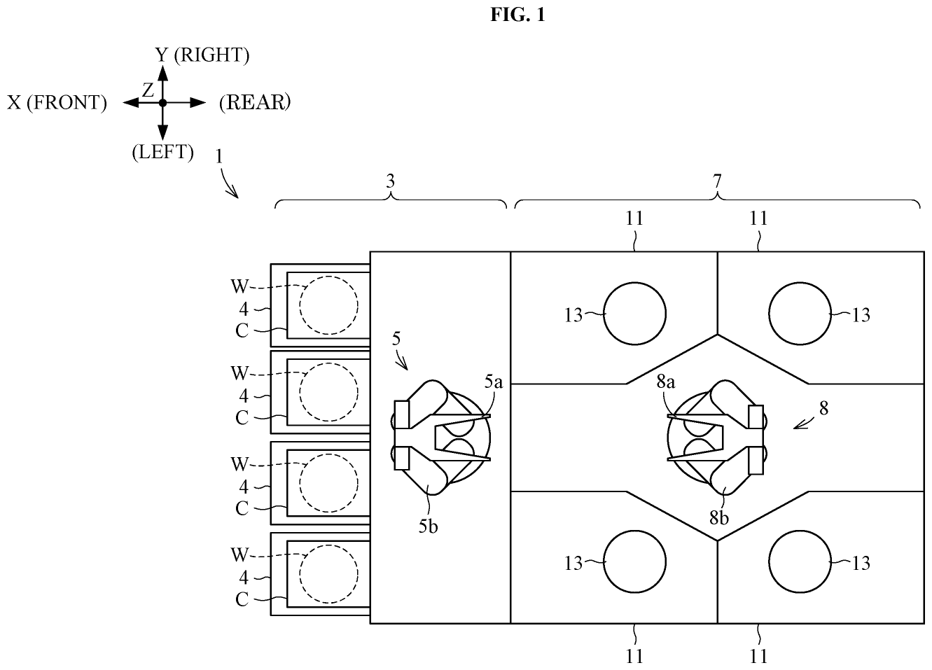

FIG. 1 is a plan view of an interior of a substrate treating apparatus according to the first embodiment. A substrate treating apparatus 1 performs treatment on a substrate W. The treatment performed on the substrate W includes a drying treatment.

Examples of the substrate W include a semiconductor wafer, a substrate for liquid crystal display, a substrate for organic electroluminescence (EL), a substrate for flat panel display (FPD), a substrate for optical display, a magnetic disk substrate, an optical disk substrate, a magneto-optical disk substrate, a substrate for photomask, and a solar cell substrate. The substrate W has a thin and flat plate shape. The substrate W has a substantially circular shape in plan view.

The substrate treating apparatus 1 includes an indexer 3, and a treating block 7. The treating block 7 is connected to the indexer 3. The indexer 3 supplies a substrate W to the treating block 7. The treating block 7 performs a treatment to the substrate W. The indexer 3 collects the substrate W from the treating block 7.

In this specification, the direction in which the indexer 3 and the treating block 7 are arranged is referred to as a “front-back direction X” for convenience. The front-back direction X is horizontal. One direction of the front-back direction X from the treating block 7 to the indexer 3 is referred to as a “forward direction”. The direction opposite to the forward direction is referred to as a “rearward direction”. A horizontal direction orthogonal to the front-back direction X is referred to as a “transverse direction Y”. One direction of the transverse direction Y is referred to as a “rightward direction”, as appropriate. The direction opposite to rightward is referred to as “leftward”. The perpendicular direction relative to the horizontal direction is referred to as a “vertical direction Z”. For reference, the drawings show front, rear, right, left, up, and down, as appropriate.

The indexer 3 includes a plurality of (e.g., four) carrier platforms 4. The carrier platforms 4 each include one carrier C placed thereon. The carrier C accommodates a plurality of substrates W. The carrier C is, for example, a front opening unified pod (FOUP), a standard mechanical interface (SMIF), or an open cassette (OC).

The indexer 3 includes a transport mechanism 5. The transport mechanism 5 is arranged rearward of the carrier platforms 4. The transport mechanism 5 transports substrates W. The transport mechanism 5 can access the carriers C placed on the carrier platforms 4, respectively. The transport mechanism 5 includes a hand 5a and a hand driving unit 5b. The hand 5a supports a substrate W. The hand driving unit 5b is coupled to the hand 5a. The hand driving unit 5b moves the hand 5a. The hand driving unit 5b moves the hand 5a in the front-back direction X, transverse direction Y, and vertical direction Z, for example. The hand driving unit 5b rotates the hand 5a in a horizontal plane, for example.

The treating block 7 includes a transport mechanism 8. The transport mechanism 8 transports substrates W. The substrates W can be delivered between the transport mechanism 5 and the transport mechanism 8. The transport mechanism 8 includes a hand 8a and a hand driving unit 8b. The hand 8a supports a substrate W. The hand driving unit 8b is coupled to the hand 8a. The hand driving unit 8b moves the hand 8a. The hand driving unit 8b moves the hand 8a in the front-back direction X, transverse direction Y, and vertical direction Z, for example. The hand driving unit 8b rotates the hand 8a in a horizontal plane, for example.

The treating block 7 includes a plurality of treating units 11. The treating units 11 are each arranged laterally of the transport mechanism 8. The treating units 11 each perform treatment on a substrate W individually.

The treating unit 11 includes a substrate holder 13. The substrate holder 13 holds a substrate W.

The transport mechanism 8 can access the treating units 11 individually. The transport mechanism 8 can deliver the substrate W onto the substrate holder 13. The transport mechanism 8 can take the substrate W from the substrate holder 13.

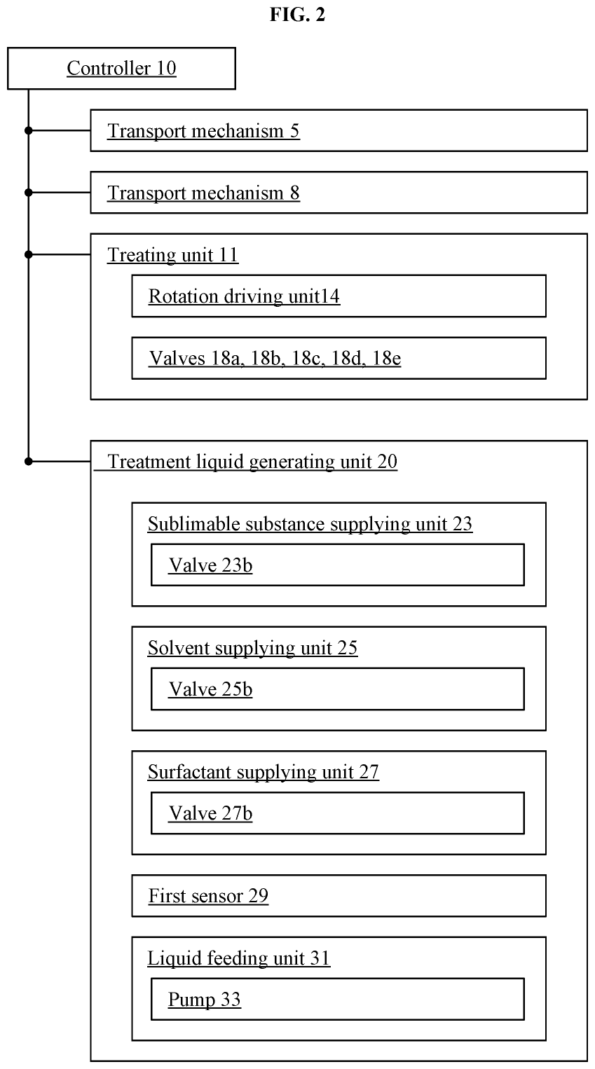

FIG. 2 is a control block diagram of the substrate treating apparatus 1. The substrate treating apparatus 1 includes a controller 10. The controller 10 controls the transport mechanisms 5, 8 and the treating units 11.

The controller 10 is implemented by a central processing unit (CPU) that performs various processes, a random-access memory (RAM) as a workspace of arithmetic processing, and a storage medium such as a fixed disk. The controller 10 contains various types of information stored in a storage medium in advance. The information stored in the controller 10 includes transportation information for controlling the transport mechanisms 5, 8, for example. The information stored in the controller 10 includes processing information for controlling the treating units 11, for example. The processing information is also called processing recipes.

The following simply describes one example of operation of the substrate treating apparatus 1.

The indexer 3 supplies substrates W to the treating block 7. Specifically, the transport mechanism 5 delivers the substrates W from the carrier C to the transport mechanism 8 of the treating block 7.

The treating block 7 distributes the substrates W from the indexer 3 to the treating unit 11. Specifically, the transport mechanism 8 transports the substrates W from the transport mechanism 5 to the substrate holders 13 of the treating units 11 individually.

The treating unit 11 performs treatment on a substrate W held by the substrate holder 13. The treating unit 11 performs a drying treatment, for example, on the substrate W.

After the treating unit 11 performs treatment on the substrate W, the treating block 7 returns the substrate W from the treating unit 11 to the indexer 3. Specifically, the transport mechanism 8 transports the substrate W from the substrate holder 13 to the transport mechanism 5.

The indexer 3 collects the substrate W from the treating block 7. Specifically, the transport mechanism 5 transports the substrate W from the transport mechanism 8 to the carrier C.

### <1-2. Construction of Treating Unit 11>

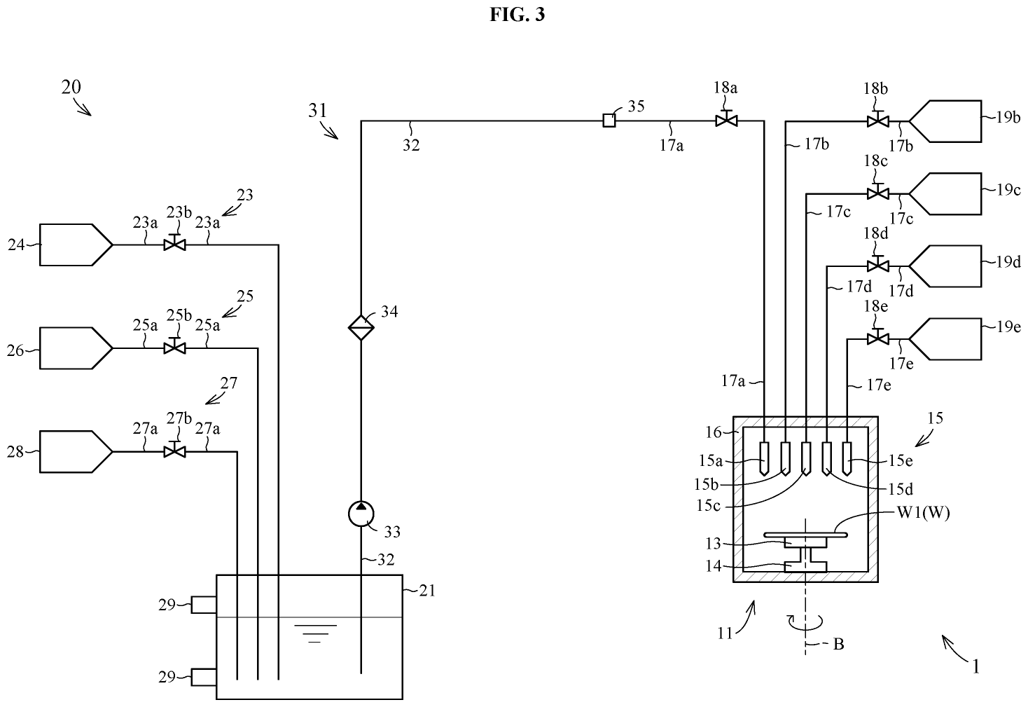

FIG. 3 shows the construction of the treating unit 11. The treating units 11 each have the same construction. The treating unit 11 is classified as a single-wafer processing unit. That is, the treating units 11 each perform treatment on only one substrate W at one time.

The substrate holder 13 holds one substrate W. The substrate holder 13 holds the substrate W in a substantially horizontal posture. The substrate holder 13 holds a peripheral edge or a lower surface of the substrate W. The lower surface of the substrate W is also called a back side of the substrate W.

The treating units 11 each include a rotation driving unit 14. The rotation driving unit 14 is connected to the substrate holder 13. The rotation driving unit 14 rotates the substrate holder 13. The substrate W held by the substrate holder 13 rotates integrally with the substrate holder 13. The substrate W held by the substrate holder 13 rotates around a rotation axis B. The rotation axis B passes through the center of the substrate W and extends in the vertical direction Z, for example.

The treating units 11 each include a first nozzle 15a, a second nozzle 15b, a third nozzle 15c, a fourth nozzle 15d, and a fifth nozzle 15e. When no distinction is made between the first to fifth nozzles 15a to 15e hereunder, they are simply referred to as a “nozzle 15”. The nozzles 15 each dispense a liquid or gas to substrate W. More specifically, the nozzles 15 each dispense a liquid or gas to an upper surface W1 of a substrate W held by the substrate holder 13. The nozzles 15 are each movable between a treating position and a standby position. The treating position is, for example, a position above the substrate W held by the substrate holder 13. The standby position is, for example, a position apart from the above of the substrate W held by the substrate holder 13.

The treating units 11 each include a casing 16. The casing 16 has a substantial box shape. The casing 16 accommodates therein the substrate holder 13, the rotation driving unit 14, and the nozzles 15. The substrates W are treated within the casing 16.

The interior of the casing 16 is kept at room temperature. The interior of the casing 16 is kept at normal pressure. Accordingly, substrates W are treated under an environment of room temperature and normal pressure. Here, the room temperature falls within a temperature range of 10 to 35 degrees centigrade, for example. The room temperature falls within a temperature range of 20 to 30 degrees centigrade, for example. The normal pressure includes normal atmospheric pressure (1 atm, 1013 hPa). The normal pressure falls within a pressure range of 0.7 to 1.3 atm, for example. In the present specification, pressure is indicated as absolute pressure relative to absolute vacuum.

The treating units 11 may each further have a cup, not shown. The cup is located inside of the casing 16. The cup is arranged around the substrate holder 13. The cup receives the liquid scattered from the substrate W held by the substrate holder 13.

The treating units 11 each include pipes 17a, 17b, 17c, 17d, and 17e. The pipes 17a to 17e are connected to the first to fifth nozzles 15a to 15e, respectively. At least part of the pipe 17a may be provided externally of the casing 16. The same arrangement of the pipe 17a is applicable to arrangement of the pipes 17b to 17e.

The treating units 11 each include valves 18a, 18b, 18c, 18d, and 18e. The valves 18a to 18e are provided on the pipes 17a to 17e, respectively. The valve 18a may be provided externally of the casing 16. The same arrangement of the valve 18a is applicable to arrangement of the valves 18b to 18e.

The substrate treating apparatus 1 includes a treatment liquid generating unit 20. The treatment liquid generating unit 20 is connected to the pipe 17a. The treatment liquid generating unit 20 is connected to the first nozzle 15a via the pipe 17a. The treatment liquid generating unit 20 is in fluid communication with the first nozzle 15a.

The treatment liquid generating unit 20 generates a treatment liquid. The treatment liquid generating unit 20 feeds the treatment liquid to the first nozzle 15a. The first nozzle 15a ejects the treatment liquid. The treatment liquid generating unit 20 may supply the treatment liquid to a plurality of treating units 11.

The first nozzle 15a corresponds to one example of the treatment liquid supplying unit in the present invention.

The pipe 17b is connected to a chemical liquid supplying source 19b. The chemical liquid supplying source 19b is connected in fluid communication with the second nozzle 15b. The chemical liquid supplying source 19b feeds a chemical liquid to the second nozzle 15b. The second nozzle 15b dispenses the chemical liquid.

The chemical liquid is, for example, an etchant. The chemical liquid includes, for example, at least either hydrofluoric acid (HF) or buffered hydrofluoric acid (BHF).

The pipe 17c is connected to a rinse liquid supplying source 19c. The rinse liquid supplying source 19c is connected in fluid communication with the third nozzle 15c. The rinse liquid supplying source 19c feeds a rinse liquid to the third nozzle 15c. The third nozzle 15c dispenses the rinse liquid.

The rinse liquid is, for example, deionized water (DIW).

The pipe 17d is connected to a replacement liquid supplying source 19d. The replacement liquid supplying source 19d is connected in fluid communication with the fourth nozzle 15d. The replacement liquid supplying source 19d feeds a replacement liquid to the fourth nozzle 15d. The fourth nozzle 15d dispenses the replacement liquid.

The replacement liquid is, for example, an organic solvent. The replacement liquid is, for example, isopropyl alcohol (IPA).

The pipe 17e is connected to a gas supplying source 19e. The gas supplying source 19e is connected in fluid communication with the fifth nozzle 15e. The gas supplying source 19e feeds gas to the fifth nozzle 15e. The fifth nozzle 15e ejects gas. The fifth nozzle 15e blows out gas.

The gas is, for example, dry gas. The dry gas has a dew point lower than room temperature. The dew point is, for example, approximately −76 degrees centigrade. Accordingly, the dry gas does not dew at room temperature. Examples of the gas include air. The gas is, for example, compressed air. The gas is, for example, inert gas. The gas is, for example, nitrogen gas.

The fifth nozzle 15e is one example of the gas supplying unit in the present invention.

The chemical liquid supplying source 19b may be an element of the substrate treating apparatus 1. For example, the chemical liquid supplying source 19b may be a chemical liquid tank included in the substrate treating apparatus 1. Alternatively, the chemical liquid supplying source 19b may not be an element of the substrate treating apparatus 1. For example, the chemical liquid supplying source 19b may be a utility setup located externally of the substrate treating apparatus 1. Likewise, the rinse liquid supplying source 19c, the replacement liquid supplying source 19d, and the gas supplying source 19e each may or may not be an element of the substrate treating apparatus 1.

Reference is made to FIG. 2. The controller 10 controls the rotation driving unit 14, and the valves 18a to 18e.

<1-3. Treatment liquid>

The following describes a treatment liquid generated by the treatment liquid generating unit 20. The treatment liquid contains a sublimable substance, a solvent, and a surfactant. The treatment liquid consists of only a sublimable substance, a solvent, and a surfactant, for example.

Here, the “sublimable substance” satisfies the following conditions E1 to E4.
Condition E1: The sublimable substance has sublimability.
Condition E2: The sublimable substance is solid at room temperature.
Condition E3: The sublimable substance is dissolvable in a solvent at room temperature.
Condition E4: The sublimable substance has vapor pressure of 0.01 Pa (absolute pressure) or more at room temperature.

Regarding the condition E1, “sublimability” means a property that a single substance, a chemical compound or a mixture changes its phase from a solid phase to a gas phase or from a gas phase to a solid phase without passing through a liquid phase.

Regarding the condition E2, it is preferred that the sublimable substance can be kept solid over a temperature range defined by room temperature.

The solvent is a liquid at room temperature. The solvent dissolves the sublimable substance.

Accordingly, the sublimable substance in the treatment liquid is dissolved in the solvent. That is, the treatment liquid contains the solvent, the sublimable substance dissolved in the solvent, and the surfactant.

The surfactant is a liquid at room temperature.

Here, a volume of the sublimable substance contained in the treatment liquid is smaller than a volume of the solvent contained in the treatment liquid. For example, the volume of the sublimable substance contained in the treatment liquid is 1% or more and 10% or less of the volume of the solvent contained in the treatment liquid. In other words, the sublimable substance and the solvent contained in the treatment liquid preferably satisfy the following relationship.

(Sublimable substance in treatment liquid):(Solvent in treatment liquid)=1:100 to 10:100 (volume ratio)

The volume of the surfactant contained in the treatment liquid is smaller than the volume of the solvent contained in the treatment liquid. For example, the volume of the surfactant contained in the treatment liquid is 0.01% or more and 10% or less of the volume of the solvent contained in the treatment liquid. In other words, the surfactant and the solvent contained in the treatment liquid preferably satisfy the following relationship.

(Surfactant in treatment liquid):(Solvent in treatment liquid)=0.01:100 to 10:100 (volume ratio)

A group of chemical compounds selectable as the solvent and a group of chemical compounds selectable as the surfactant may overlap each other. However, it is prohibited to select the same chemical compound as the solvent and the surfactant at the same time. It is prohibited to select a chemical compound having the same composition as the solvent and the surfactant at the same time. For example, methanol belongs to the group of chemical compounds selectable as the solvent and also belongs to the group of chemical compounds selectable as the surfactant. For example, methanol is occasionally selected as the solvent, and is also occasionally selected as the surfactant. However, when the solvent contains methanol, the surfactant does not contain methanol. That is, when the solvent contains methanol, the surfactant is prohibited from containing methanol. For example, when the solvent does not contain methanol, the surfactant may contain methanol. That is, when the solvent does not contain methanol, the surfactant is allowed to contain methanol.

Here, the treatment liquid satisfies a first condition F1 and a second condition F2 as under. Specifically, the surfactant and the solvent contained in the treatment liquid satisfy the first condition F1 and the second condition F2.

First Condition F1: The surfactant has an octanol-water partition coefficient LogPow of −1 or more and 1 or less.
Second Condition F2: Vapor pressure Pc of the surfactant at room temperature is 0.9 times or more vapor pressure Pb of the solvent at room temperature, and 3 times or less vapor pressure Pb of the solvent at room temperature.

Here, the treatment liquid preferably satisfies a third condition F3 as under. Specifically, the solvent and the sublimable substance contained in the treatment liquid preferably satisfy the third condition F3.

Third Condition F3: Vapor pressure Pb of the solvent at room temperature is higher than vapor pressure Pa of the sublimable substance at room temperature.

Moreover, the treatment liquid preferably satisfies a fourth condition as under. Specifically, the surfactant and the sublimable substance contained in the treatment liquid preferably satisfy the fourth condition F4.

Fourth Condition F4: Vapor pressure Pc of the surfactant at room temperature is higher than vapor pressure Pa of the sublimable substance at room temperature.

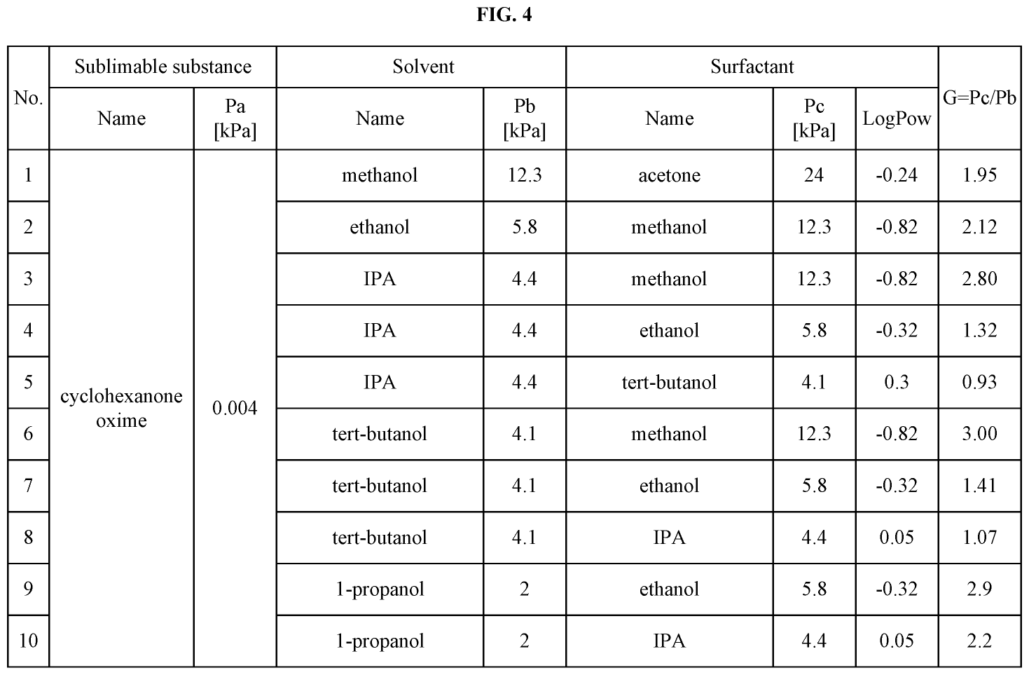

FIGS. 4 to 11 are each a table exemplarily illustrating the sublimable substance, the solvent, and the surfactant contained in the treatment liquid. Numeral numbers (Nos.) 1 to 78 shown in FIGS. 4 to 11 each denote a number of the treatment liquid. The treatment liquids of Nos. 1 to 78 each satisfy the first condition F1 and the second condition F2. Also, the treatment liquids of Nos. 1 to 78 shown in FIGS. 4 to 11 each satisfy the third condition F3. Also, the treatment liquids of Nos. 1 to 78 shown in FIGS. 4 to 11 each satisfy the fourth condition F4.

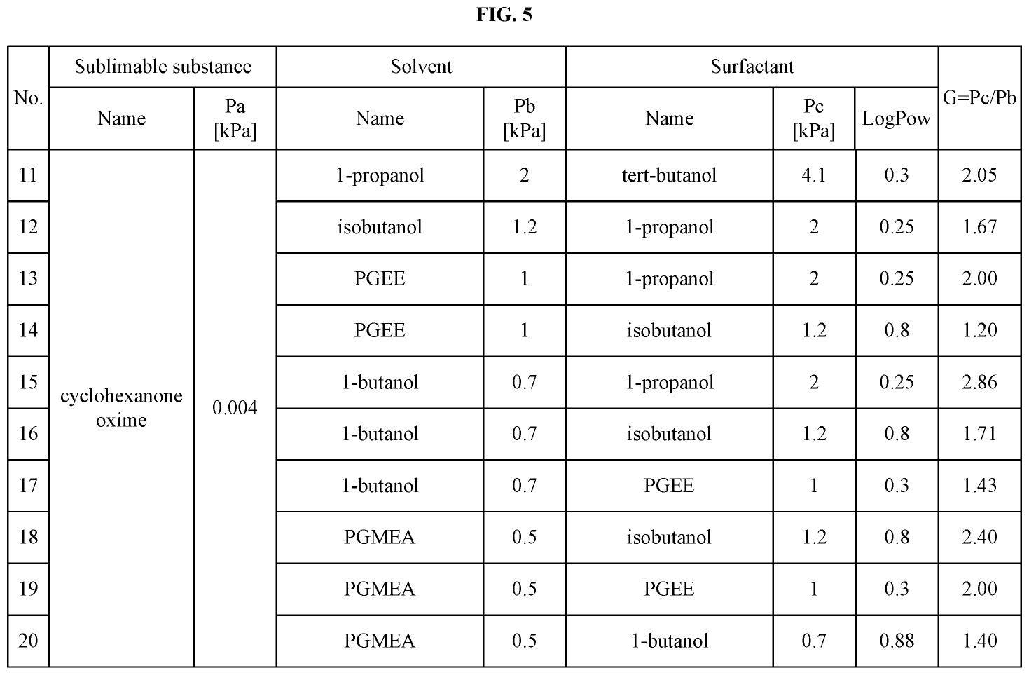

Reference is made to FIGS. 4 and 5. FIGS. 4 and 5 illustrate treatment liquids of Nos. 1 to 20. The sublimable substance is cyclohexanone oxime. The solvent and the surfactant correspond to one selected from the following features a1) to a20). Here, the treatment liquid of No. 1 corresponds to a treatment liquid containing cyclohexanone oxime, and the solvent and the surfactant defined in the feature a1). In other words, the treatment liquid of No. 1 contains cyclohexanone oxime, and also contains the solvent and the surfactant defined in the feature a1). Likewise, the treatment liquids of Nos. 2 to 20 correspond to treatment liquids containing cyclohexanone oxime, and the solvent and the surfactant defined in the features a2) to a20), respectively.
a1) The solvent is methanol, and the surfactant is acetone.
a2) The solvent is ethanol, and the surfactant is methanol.
a3) The solvent is isopropyl alcohol (IPA), and the surfactant is methanol.
a4) The solvent is isopropyl alcohol (IPA), and the surfactant is ethanol.
a5) The solvent is isopropyl alcohol (IPA), and the surfactant is tert-butanol.
a6) The solvent is tert-butanol, and the surfactant is methanol.
a7) The solvent is tert-butanol, and the surfactant is ethanol.
a8) The solvent is tert-butanol, and the surfactant is isopropyl alcohol (IPA).
a9) The solvent is 1-propanol, and the surfactant is ethanol.
a10) The solvent is 1-propanol, and the surfactant is isopropyl alcohol (IPA).
a11) The solvent is 1-propanol, and the surfactant is tert-butanol.
a12) The solvent is isobutanol, and the surfactant is 1-propanol.
a13) The solvent is 1-ethoxy-2-propanol (PGEE), and the surfactant is 1-propanol.
a14) The solvent is 1-ethoxy-2-propanol (PGEE), and the surfactant is isobutanol.
a15) The solvent is 1-butanol, and the surfactant is 1-propanol.
a16) The solvent is 1-butanol, and the surfactant is isobutanol.
a17) The solvent is 1-butanol, and the surfactant is 1-ethoxy-2-propanol (PGEE).
a18) The solvent is propylene glycol monomethyl ether acetate (PGMEA), and the surfactant is isobutanol.
a19) the solvent is propylene glycol monomethyl ether acetate (PGMEA), and the surfactant is 1-ethoxy-2-propanol (PGEE).
a20) The solvent is propylene glycol monomethyl ether acetate (PGMEA), and the surfactant is 1-butanol.

FIGS. 4 and 5 each illustrate vapor pressure Pa of the sublimable substance at room temperature. FIGS. 4 and 5 each illustrate vapor pressure Pb of the solvent at room temperature. FIGS. 4 and 5 each illustrate vapor pressure Pc of the surfactant at room temperature. FIGS. 4 and 5 each illustrate octanol-water partition coefficient LogPow of the surfactant. FIGS. 4 and 5 each illustrate values G obtained by dividing the vapor pressure Pc by the vapor pressure Pb.

The vapor pressure Pa of cyclohexanone oxime is measured at a temperature of 25 degrees centigrade. The vapor pressure Pb and Pc of PGEE each is measured at a temperature of 25 degrees centigrade. The vapor pressure Pb of the solvent other than PGEE is measured at temperature of 20 degrees centigrade. The vapor pressure Pc of the surfactant other than PGEE is measured at a temperature of 20 degrees centigrade.

In the treatment liquids of Nos. 1 to 20, the surfactant has an octanol-water partition coefficient LogPow of −1 or more and 1 or less. That is, the surfactant has an octanol-water partition coefficient LogPow of −1 or more and 1 or less in the case where the surfactant corresponds to any of the features of a1) to a20). Accordingly, the treatment liquids of Nos. 1 to 20 satisfy the first condition F1.

In the treatment liquids of Nos. 1 to 20, the values G fall between 0.9 and 3, inclusive. That is, the vapor pressure Pc of the surfactant is 0.9 times or more and 3 times or less vapor pressure Pb of the solvent in the case where the solvent and the surfactant correspond to any of the features of a1) to a20). Accordingly, the treatment liquids of Nos. 1 to 20 satisfy the second condition F2.

In the treatment liquids of Nos. 1 to 20, the vapor pressure Pb of the solvent is higher than the vapor pressure Pa of cyclohexanone oxime. That is, the vapor pressure Pb of the solvent is higher than the vapor pressure Pa of cyclohexanone oxime in the case where the solvent corresponds to any of the features of a1) to a20). Accordingly, the treatment liquids of Nos. 1 to 20 each satisfy the third condition F3.

In the treatment liquids of Nos. 1 to 20, the vapor pressure Pc of the surfactant is higher than the vapor pressure Pa of cyclohexanone oxime. That is, the vapor pressure Pc of the surfactant is higher than the vapor pressure Pa of cyclohexanone oxime in the case where the surfactant corresponds to any of the features of a1) to a20). Accordingly, the treatment liquids of Nos. 1 to 20 satisfy the fourth condition F4.

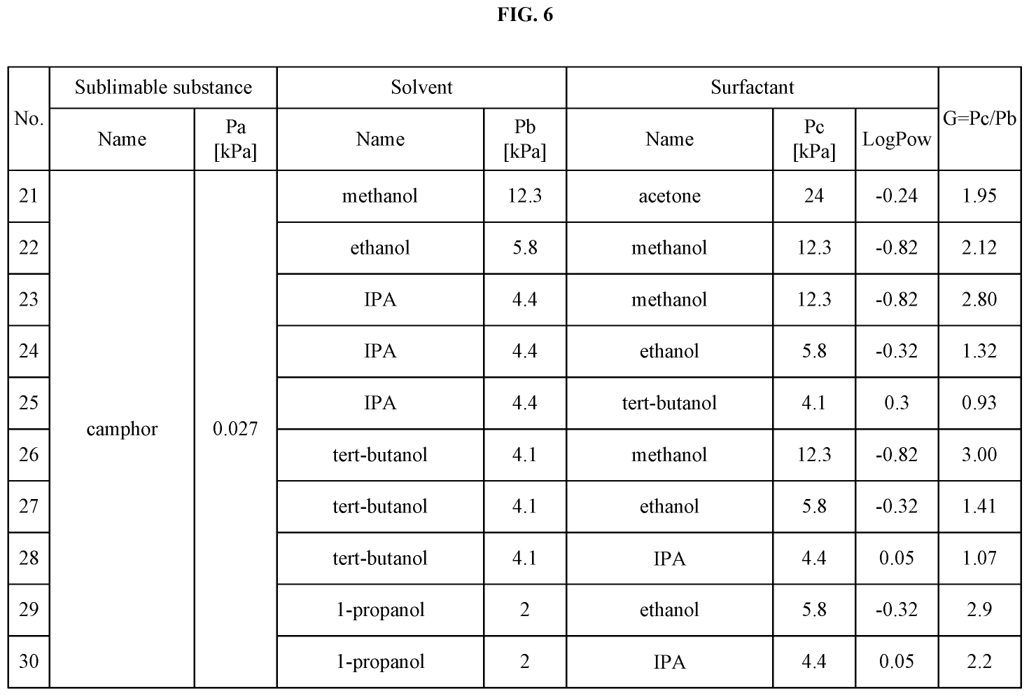

Reference is made to FIGS. 6 and 7. FIGS. 6 and 7 illustrate treatment liquids Nos. 21 to 40. The sublimable substance is camphor. The solvent and the surfactant correspond to one selected from the features a1) to a20) described above. Here, the treatment liquid of No. 21 corresponds to a treatment liquid containing camphor, and the solvent and the surfactant defined in the feature a1). In other words, the treatment liquid of No. 21 contains camphor, and also contains the solvent and the surfactant defined in the feature a1). Likewise, the treatment liquids of Nos. 22 to 40 correspond to treatment liquids containing camphor, and the solvent and the surfactant defined in the features a2) to a20), respectively.

FIGS. 6 and 7 each illustrate vapor pressure Pa of the camphor at room temperature. The vapor pressure Pa of the camphor is measured at a temperature of 25 degrees centigrade.

As described above, the surfactant corresponds to an octanol-water partition coefficient LogPow of −1 or more and 1 or less in the case where the surfactant has any of the features of a1) to a20). Accordingly, also in the treatment liquids of Nos. 21 to 40, the surfactant has an octanol-water partition coefficient LogPow of −1 or more and 1 or less. Accordingly, the treatment liquids of Nos. 21 to 40 each satisfy the first condition F1.

As described above, the vapor pressure Pc of the surfactant is 0.9 times or more and 3 times or less vapor pressure Pb of the solvent in the case where the solvent and the surfactant correspond to any of the features of a1) to a20). Accordingly, the vapor pressure Pc of the surfactant is 0.9 times or more and 3 times or less vapor pressure Pb of the solvent also in the treatment liquids of Nos. 21 to 40. Accordingly, the treatment liquids of Nos. 21 to 40 each satisfy the second condition F2.

In the treatment liquids of Nos. 21 to 40, the vapor pressure Pb of the solvent is higher than the vapor pressure Pa of the camphor. That is, the vapor pressure Pb of the solvent is higher than the vapor pressure Pa of the camphor in the case where the solvent corresponds to any of the features of a1) to a20). Accordingly, the treatment liquids of Nos. 21 to 40 each satisfy the third condition F3.

In the treatment liquids of Nos. 21 to 40, the vapor pressure Pc of the surfactant is higher than the vapor pressure Pa of the camphor. That is, the vapor pressure Pc of the surfactant is higher than the vapor pressure Pa of the camphor in the case where the surfactant corresponds to any of the features of a1) to a20). Accordingly, the treatment liquids of Nos. 21 to 40 each satisfy the fourth condition F4.

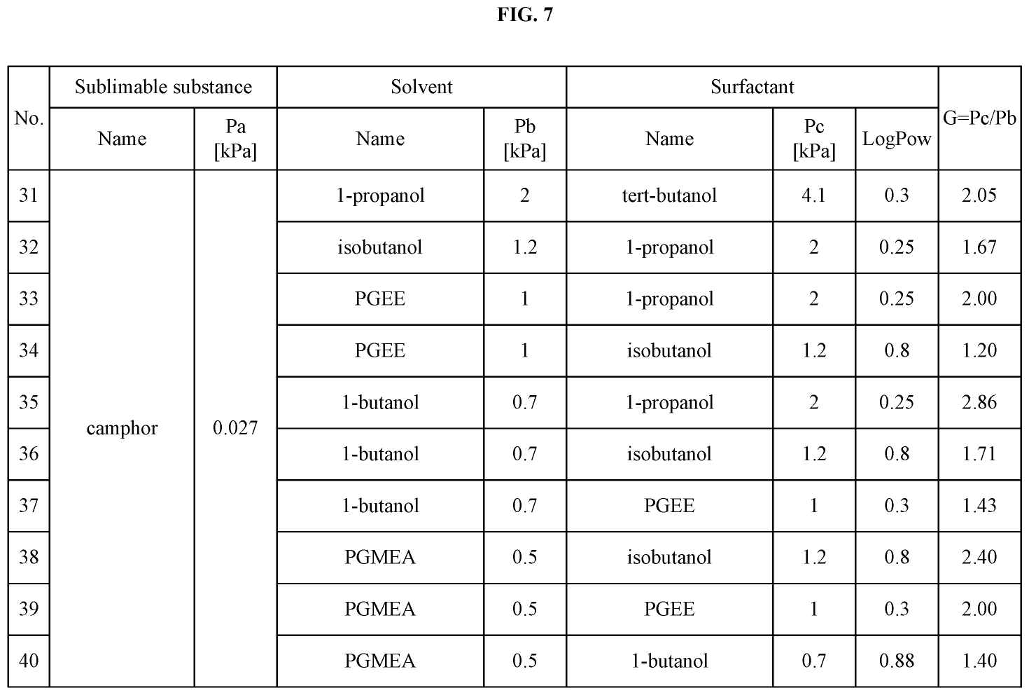

Reference is made to FIGS. 8 and 9. FIGS. 8 and 9 illustrate treatment liquids of Nos. 41 to 60. The sublimable substance is ε-caprolactam. The solvent and the surfactant corresponds to one selected from the features a1) to a20) described above.

Here, the treatment liquid of No. 41 corresponds to a treatment liquid containing ε-caprolactam, and the solvent and the surfactant defined in the feature a1). In other words, the treatment liquid of No. 41 contains ε-caprolactam, and also contains the solvent and the surfactant defined in the feature a1). Likewise, the treatment liquids of Nos. 42 to 60 correspond to treatment liquids containing ε-caprolactam, and the solvent and the surfactant defined in the features a2) to a20), respectively.

FIGS. 8 and 9 each illustrate vapor pressure Pa of the ε-caprolactam at room temperature. The vapor pressure Pa of the ε-caprolactam is measured at a temperature of 25 degrees centigrade.

As described above, the surfactant has an octanol-water partition coefficient LogPow of −1 or more and 1 or less in the case where the surfactant corresponds to any of the features of a1) to a20). Accordingly, also in the treatment liquids of Nos. 41 to 60, the surfactant has an octanol-water partition coefficient LogPow of −1 or more and 1 or less. Accordingly, the treatment liquids of Nos. 41 to 60 each satisfy the first condition F1.

As described above, the vapor pressure Pc of the surfactant is 0.9 times or more and 3 times or less vapor pressure Pb of the solvent in the case where the solvent and the surfactant correspond to any of the features of a1) to a20). Accordingly, the vapor pressure Pc of the surfactant is 0.9 times or more and 3 times or less vapor pressure Pb of the solvent also in the treatment liquids of Nos. 41 to 60. Accordingly, the treatment liquids of Nos. 41 to 60 each satisfy the second condition F2.

In the treatment liquids of Nos. 41 to 60, the vapor pressure Pb of the solvent is higher than the vapor pressure Pa of ε-caprolactam. That is, the vapor pressure Pb of the solvent is higher than the vapor pressure Pa of ε-caprolactam in the case where the solvent corresponds to any of the features of a1) to a20). Accordingly, the treatment liquids of Nos. 41 to 60 each satisfy the third condition F3.

In the treatment liquids of Nos. 41 to 60, the vapor pressure Pc of the surfactant is higher than the vapor pressure Pa of ε-caprolactam. That is, the vapor pressure Pc of the surfactant is higher than the vapor pressure Pa of ε-caprolactam in the case where the surfactant corresponds to any of the features of a1) to a20). Accordingly, the treatment liquids of Nos. 41 to 60 each satisfy the fourth condition F4.

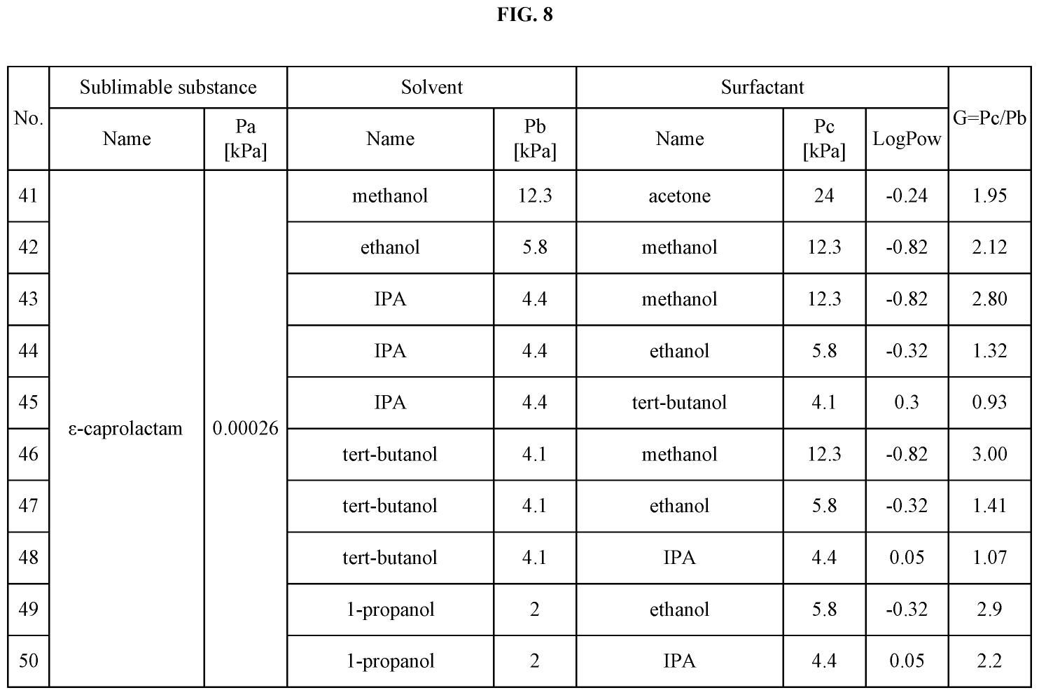

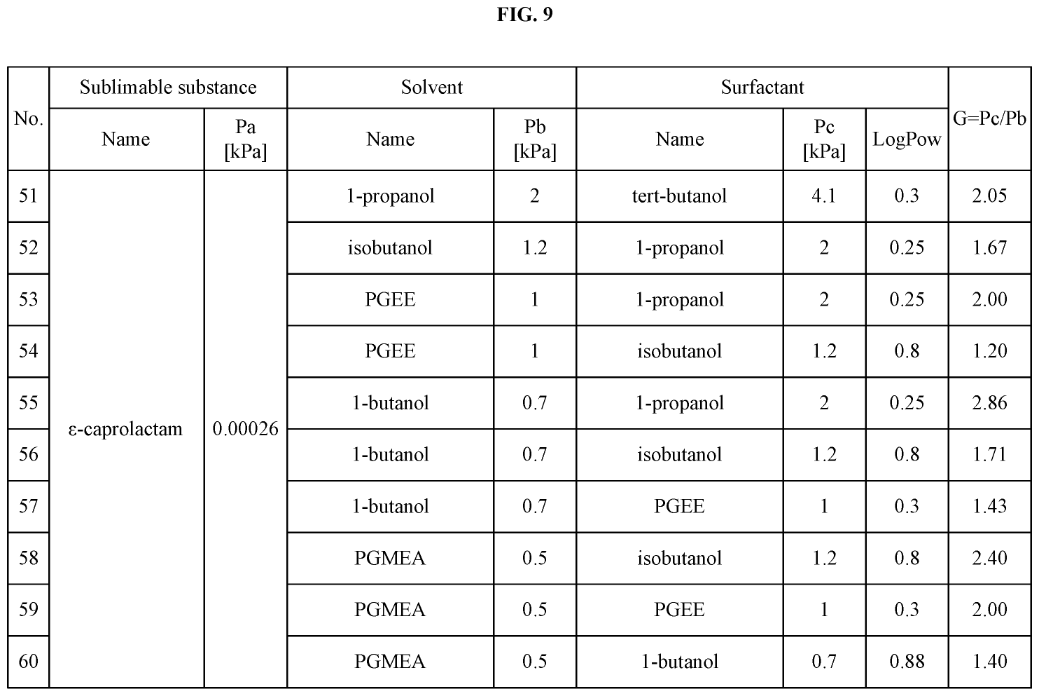

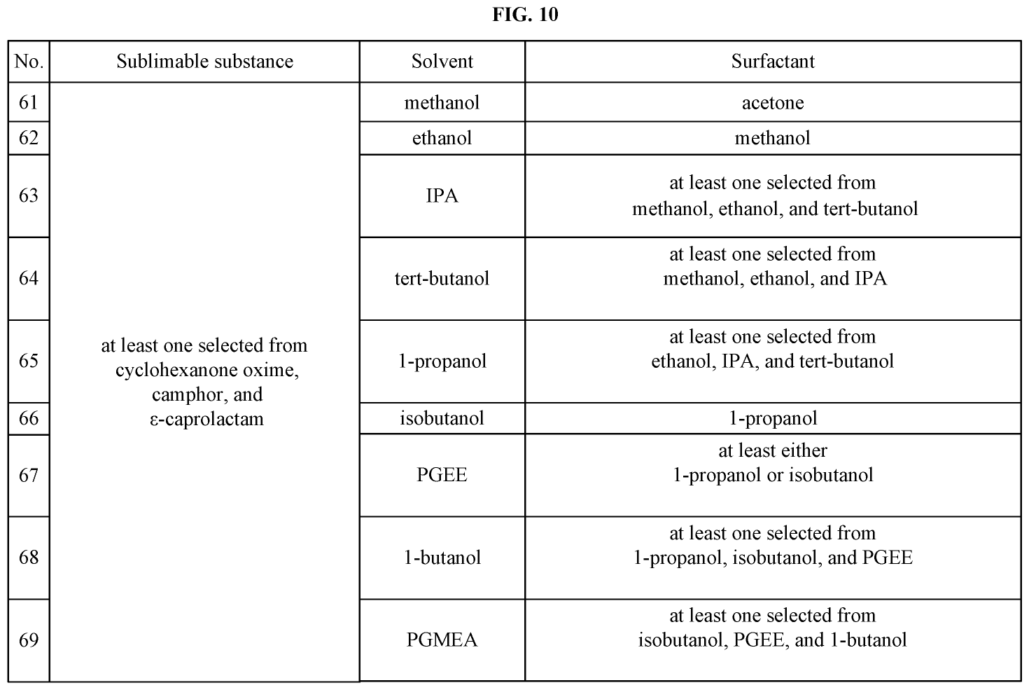

Reference is made to FIG. 10. FIG. 10 illustrates treatment liquids of Nos. 61 to 69. The sublimable substance is at least one selected from cyclohexanone oxime, camphor, and ε-caprolactam, for example. The solvent and the surfactant corresponds to one selected from the following features b1) to b9). Here, the treatment liquid of No. 61 corresponds to a treatment liquid containing the sublimable substance, and the solvent and the surfactant defined in the feature b1). In other words, the treatment liquid of No. 61 contains at least one selected from cyclohexanone oxime, camphor, and ε-caprolactam, and also contains the solvent and the surfactant defined in the feature b1). Likewise, the treatment liquids of Nos. 62 to 69 correspond to treatment liquids containing the sublimable substance, and also containing the solvent and the surfactant defined in the features b2) to b9), respectively.

The solvent and the surfactant correspond to one selected from the following features b1) to b9).
b1) The solvent is methanol, and the surfactant is acetone.
b2) The solvent is ethanol, and the surfactant is methanol.
b3) The solvent is isopropyl alcohol (IPA), and the surfactant is at least one selected from methanol, ethanol, and tert-butanol.
b4) The solvent is tert-butanol, and the surfactant is at least one selected from methanol, ethanol, and isopropyl alcohol (IPA).
b5) The solvent is 1-propanol, and the surfactant is at least one selected from ethanol, isopropyl alcohol (IPA), and tert-butanol.
b6) The solvent is isobutanol, and the surfactant is 1-propanol.
b7) The solvent is 1-ethoxy-2-propanol (PGEE), and the surfactant is at least either 1-propanol or isobutanol.
b8) The solvent is 1-butanol, and the surfactant is at least one selected from 1-propanol, isobutanol, and 1-ethoxy-2-propanol (PGEE).
b9) The solvent is propylene glycol monomethyl ether acetate (PGMEA), and the surfactant is at least one selected from isobutanol, 1-ethoxy-2-propanol (PGEE), and 1-butanol.

Now description will be made of the language “at least one”. For example, the language “M is at least one selected from Ma, Mb, and Mc” means any one selected from features d1) to d7) as under.
d1) M is Ma.
d2) M is Mb.
d3) M is Mc.
d4) M is Ma and Mb.
d5) M is Ma and Mc.
d6) M is Mb and Mc.
d7) M is Ma, Mb, and Mc.

Here, the term M is, for example, a sublimable substance, a solvent, or a surfactant. The terms Ma, Mb, and Mc are each a name of a chemical compound.

The feature b1) is same as the feature a1). Accordingly, the treatment liquid of No. 61 satisfies the first to fourth conditions F1 to F4. From the same reason, the treatment liquids of Nos. 62 and 66 each satisfy the first to fourth conditions F1 to F4.

The solvent of the feature b3) is same as the solvent of each of the features a3) to a5). The surfactant of the feature b3) is at least one selected from the surfactants of the features a3) to a5). Accordingly, the treatment liquid of No. 63 satisfies the first to fourth conditions F1 to F4. From the same reason, the treatment liquids of Nos. 64, 65, and 67 to 69 each satisfy the first to fourth conditions F1 to F4.

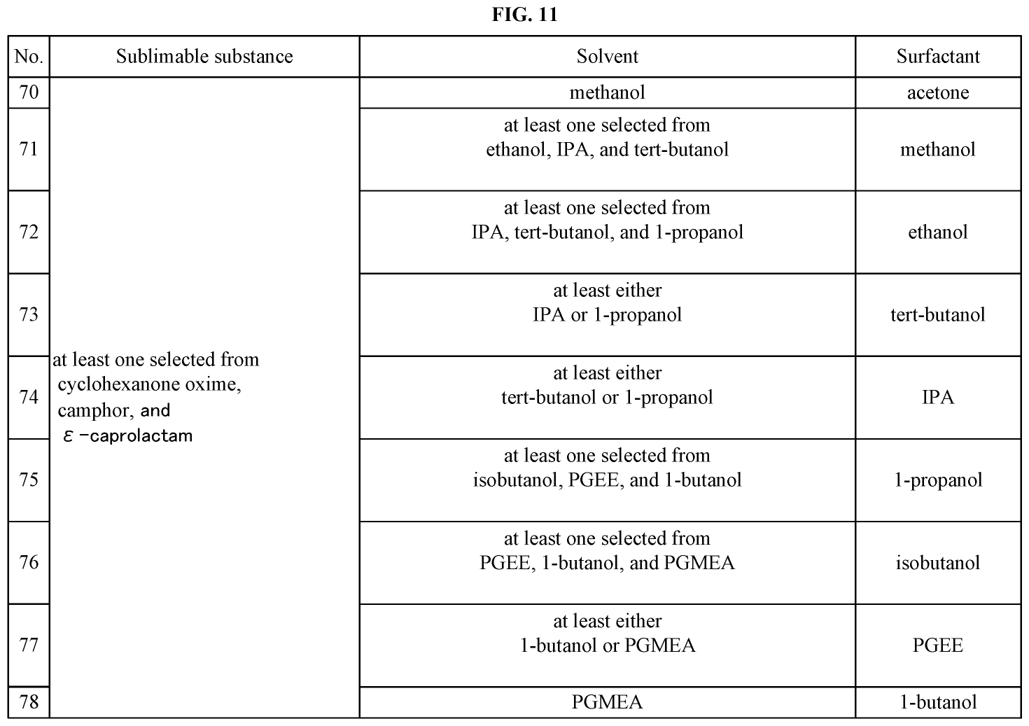

Reference is made to FIG. 11. FIG. 11 illustrates treatment liquids of Nos. 70 to 78. The sublimable substance is at least one selected from cyclohexanone oxime, camphor, and ε-caprolactam, for example. The solvent and the surfactant correspond to one selected from the following features c1) to c9). Here, the treatment liquid of No. 70 corresponds to a treatment liquid containing the sublimable substance, and the solvent and the surfactant defined in the feature c1). In other words, the treatment liquid of No. 70 contains at least one selected from cyclohexanone oxime, camphor, and ε-caprolactam, and also contains the solvent and the surfactant defined in the feature c1). Likewise, the treatment liquids of Nos. 71 to 78 correspond to treatment liquids containing the sublimable substance, and also containing the solvent and the surfactant defined in the features c2) to c9), respectively.

The solvent and the surfactant correspond to one selected from the following features c1) to c9).
c1) The solvent is methanol, and the surfactant is acetone.
c2) The solvent is at least one selected from ethanol, isopropyl alcohol (IPA), and tert-butanol, and the surfactant is methanol.
c3) The solvent is at least one selected from isopropyl alcohol (IPA), tert-butanol, and 1-propanol, and the surfactant is ethanol.
c4) The solvent is at least either isopropyl alcohol (IPA) or 1-propanol, and the surfactant is tert-butanol.
c5) The solvent is at least either tert-butanol or 1-propanol, and the surfactant is isopropyl alcohol (IPA).
c6) The solvent is at least one selected from isobutanol, 1-ethoxy-2-propanol (PGEE), and 1-butanol, and the surfactant is 1-propanol.
c7) The solvent is at least one selected from 1-ethoxy-2-propanol (PGEE), 1-butanol, and propylene glycol monomethyl ether acetate (PGMEA), and the surfactant is isobutanol.
c8) The solvent is at least either 1-butanol or propylene glycol monomethyl ether acetate (PGMEA), and the surfactant is 1-ethoxy-2-propanol (PGEE).
c9) The solvent is propylene glycol monomethyl ether acetate (PGMEA), and the surfactant is 1-butanol.

The feature c1) is same as the feature a1). Accordingly, the treatment liquid of No. 70 satisfies the first to fourth conditions F1 to F4. From the same reason, the treatment liquid of No. 78 satisfies the first to fourth conditions F1 to F4.

The surfactant of the feature c2) is same as the surfactants of the features a2), a3), and a6). The solvent of the feature c2) is at least one selected from the solvent of the features a2), a3), and a6). Accordingly, the treatment liquid of No. 71 satisfies the first to fourth conditions F1 to F4. From the same reason, the treatment liquids of Nos. 72 to 77 each satisfy the first to fourth conditions F1 to F4.

### <1-4. Construction of Treatment Liquid Generating Unit 20>

Reference is made to FIG. 3. The treatment liquid generating unit 20 generates a treatment liquid containing a sublimable substance, a solvent, and a surfactant.

The treatment liquid generating unit 20 includes a first tank 21. The first tank 21 is in fluid communication with the first nozzle 15a. The first tank 21 is connected to the first nozzle 15a. In the first embodiment, the treatment liquid generating unit 20 generates the treatment liquid in the first tank 21. The treatment liquid is generated under an environment of room temperature. The treatment liquid is generated under an environment of normal pressure. The treatment liquid generating unit 20 stores the generated treatment liquid in the first tank 21. The treatment liquid is stored under an environment of room temperature. The treatment liquid is stored under an environment of normal pressure.

The treatment liquid generating unit 20 includes a sublimable substance supplying unit 23, a solvent supplying unit 25, and a surfactant supplying unit 27. The sublimable substance supplying unit 23 supplies the sublimable substance to the first tank 21. The solvent supplying unit 25 supplies the solvent to the first tank 21. The surfactant supplying unit 27 supplies the surfactant to the first tank 21. The sublimable substance, the solvent, and the surfactant are mixed within the first tank 21. This results in generation of the treatment liquid containing the sublimable substance, the solvent, and the surfactant.

The sublimable substance supplying unit 23 includes a pipe 23a and a valve 23b, for example. The pipe 23a is in fluid communication with the first tank 21. The pipe 23a is connected to the first tank 21. The pipe 23a is also in fluid communication with a sublimable substance supplying source 24. The pipe 23a is connected to the sublimable substance supplying source 24. The valve 23b is provided on the pipe 23a. When the valve 23b is opened, the sublimable substance supplying source 24 supplies the sublimable substance to the first tank 21 through the pipe 23a.

The solvent supplying unit 25 includes a pipe 25a and a valve 25b, for example. The pipe 25a is in fluid communication with the first tank 21. The pipe 25a is connected to the first tank 21. The pipe 25a is also in fluid communication with a solvent supplying source 26. The pipe 25a is connected to the solvent supplying source 26. The valve 25b is provided on the pipe 25a. When the valve 25b is opened, the solvent supplying source 26 supplies the solvent to the first tank 21 through the pipe 25a.

The surfactant supplying unit 27 includes a pipe 27a and a valve 27b, for example. The pipe 27a is in fluid communication with the first tank 21. The pipe 27a is connected to the first tank 21. The pipe 27a is also in fluid communication with a surfactant supplying source 28. The pipe 27a is connected to the surfactant supplying source 28. The valve 27b is provided on the pipe 27a. When the valve 27b is opened, the surfactant supplying source 28 supplies the surfactant to the first tank 21 through the pipe 27a.

The treatment liquid generating unit 20 includes at least one or more (e.g., two) first sensors 29. The first sensor 29 detects an amount of the treatment liquid stored in the first tank 21. The first sensor 29 is attached to the first tank 21, for example. The first sensor 29 detects a height position of a liquid level of the treatment liquid stored in the first tank 21, for example. The first sensor 29 is, for example, a liquid level sensor.

The treatment liquid generating unit 20 also feeds the treatment liquid to the first nozzle 15a. The treatment liquid generating unit 20 includes a liquid feeding unit 31. The liquid feeding unit 31 feeds the treatment liquid from the first tank 21 to the first nozzle 15a.

Specifically, the liquid feeding unit 31 includes a pipe 32, a pump 33, a filter 34, and a joint 35. The pipe 32 is connected in fluid communication with the first tank 21. The pipe 32 is connected to the first tank 21. The pipe 32 extends from the first tank 21 to the pipe 17a. The pump 33 is provided on the pipe 32. The pump 33 feeds the treatment liquid from the first tank 21 to the pipe 32. The filter 34 is provided on the pipe 32. The filter 34 filters the treatment liquid that flows in the pipe 32. The filter 34 removes foreign substances from the treatment liquid. The joint 35 is connected to the pipe 32. The joint 35 is also connected to the pipe 17a. The pipes 32 and 17a are in fluid communication with each other via the joint 35. The pipe 32 is in fluid communication with the first nozzle 15a. The first tank 21 is connected to the first nozzle 15a via the pipes 32 and 17a. Accordingly, the pump 33 feeds the treatment liquid from the first tank 21 to the pipe 17a (first nozzle 15a).

Reference is made to FIG. 2. The controller 10 controls the treatment liquid generating unit 20. The controller 10 is communicably and electrically connected to the treatment liquid generating unit 20.

The controller 10 controls the sublimable substance supplying unit 23, the solvent supplying unit 25, and the surfactant supplying unit 27. The controller 10 controls the valves 23b, 25b, and 27b.

The controller 10 obtains detection results of the first sensor 29.

The controller 10 controls the liquid feeding unit 31. The controller 10 controls the pump 33.

The controller 10 contains treatment liquid generating information for controlling the treatment liquid generating unit 20. The treatment liquid generating information is stored in advance in the storage medium of the controller 10. The treatment liquid generating information defines a compound ratio of the sublimable substance, the solvent, and the surfactant contained in the treatment liquid, for example.

### <1-5. Operation Example of Treatment Liquid Generating Unit 20 and Treating Unit 11>

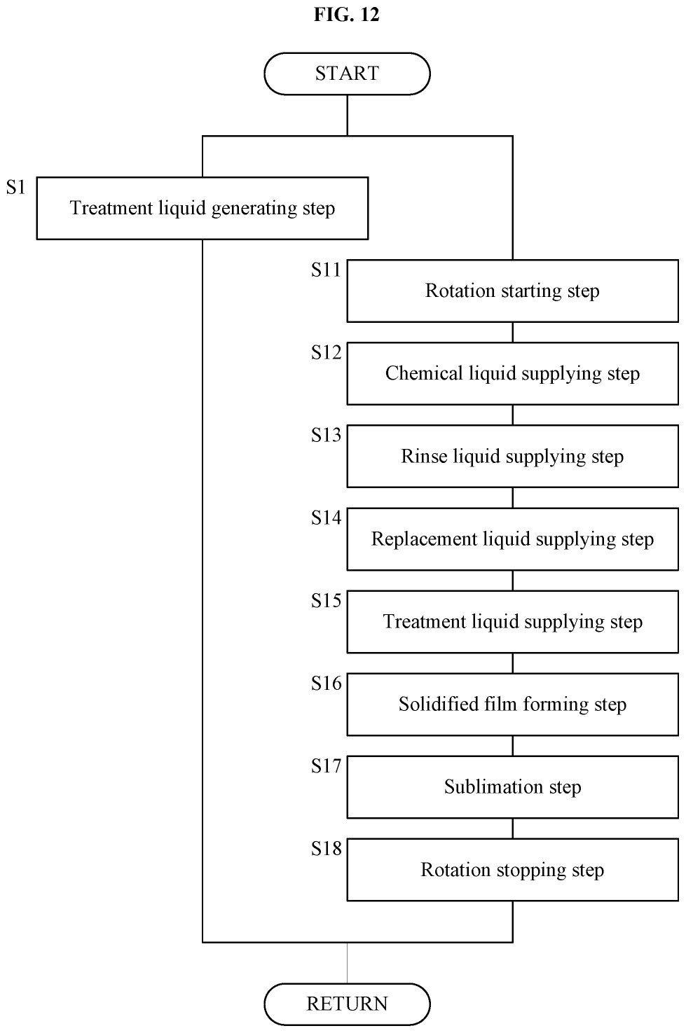

FIG. 12 is a flow chart showing procedures of the substrate treating method. The substrate treating method includes a Step S1 and Steps S11 to S18. The treatment liquid generating unit 20 performs the Step S1. The treating units 11 substantially perform the Steps S11 to S18. The Step S1 is executed in parallel with the Steps S11 to S18. The treatment liquid generating unit 20 and the treating units 11 operate in accordance with control by the controller 10.

### Step S1: Treatment Liquid Generating Step

The treatment liquid generating unit 20 generates a treatment liquid. Specifically, the sublimable substance supplying unit 23 supplies the sublimable substance to the first tank 21. The solvent supplying unit 25 supplies the solvent to the first tank 21. The surfactant supplying unit 27 supplies the surfactant to the first tank 21. Accordingly, the treatment liquid is generated in the first tank 21. Then, the treatment liquid is stored in the first tank 21.

The first sensor 29 detects an amount of the treatment liquid stored in the first tank 21. The controller 10 monitors detection results of the first sensor 29.

The controller 10 starts and stops the treatment liquid generating step in accordance with detection results of the first sensor 29. For example, when an amount of the treatment liquid stored in the first tank 21 is smaller than a first threshold, the controller 10 starts the treatment liquid generating step. Accordingly, the treatment liquid generating unit 20 starts generation of the treatment liquid. As a result, the treatment liquid stored in the first tank 21 increases. For example, when an amount of the treatment liquid stored in the first tank 21 is larger than a second threshold, the controller 10 stops the treatment liquid generating step. The second threshold is larger than the first threshold. Accordingly, the treatment liquid generating unit 20 stops generation of the treatment liquid. As a result, increase in treatment liquid stored in the first tank 21 stops. The first threshold and the second threshold are set in advance, for example. The first threshold and the second threshold are defined in the treatment liquid generating information, for example.

### Step S11: Rotation Starting Step

The substrate holder 13 holds a substrate W. The substrate W is held by the substrate holder 13 in a substantially horizontal posture. The rotation driving unit 14 rotates the substrate holder 13. The substrate W held by the substrate holder 13 starts rotation. The Steps S12 to S17 are executed while the substrate W rotates.

### Step S12: Chemical Liquid Supplying Step

The second nozzle 15b supplies chemical liquid to the substrate W. Specifically, the valve 18b opens. The second nozzle 15b supplies the chemical liquid to the substrate W held by the substrate holder 13. The second nozzle 15b dispenses the chemical liquid onto the upper surface W1 of the substrate W. The chemical liquid is supplied onto the upper surface W1 of the substrate W. Then, the valve 18b closes. The second nozzle 15b stops supplying the chemical liquid.

### Step S13: Rinse Liquid Supplying Step

The third nozzle 15c supplies a rinse liquid to the substrate W. Specifically, the valve 18c opens. The third nozzle 15c supplies the rinse liquid to the substrate W held by the substrate holder 13. The third nozzle 15c dispenses the rinse liquid onto the upper surface W1 of the substrate W. The rinse liquid is supplied onto the upper surface W1 of the substrate W. The rinse liquid cleans the substrate W. The rinse liquid removes the chemical liquid from the substrate W. Then, the valve 18c closes. The third nozzle 15c stops supplying the rinse liquid.

### Step S14: Replacement Liquid Supplying Step

The fourth nozzle 15d supplies a replacement liquid to the substrate W. Specifically, the valve 18d opens. The fourth nozzle 15d supplies the replacement liquid to the substrate W held by the substrate holder 13. The fourth nozzle 15d dispenses the replacement liquid onto the upper surface W1 of the substrate W. The replacement liquid is supplied onto the upper surface W1 of the substrate W. As a result, the rinse liquid on the substrate W is replaced with the replacement liquid. In other words, the replacement liquid removes the rinse liquid from the substrate W. Then, the valve 18d closes. The fourth nozzle 15d stops supplying the replacement liquid.

### Step S15: Treatment Liquid Supplying Step

The treatment liquid generating unit 20 feeds the treatment liquid, generated in the treatment liquid generating step, to the first nozzle 15a. Specifically, the pump 33 feeds the treatment liquid from the first tank 21 to the pipe 17a. The valve 18a opens. The first nozzle 15a supplies the treatment liquid to the substrate W held by the substrate holder 13. The first nozzle 15a dispenses the treatment liquid onto the upper surface W1 of the substrate W. The treatment liquid is supplied onto the upper surface W1 of the substrate W. As a result, the replacement liquid on the substrate W is replaced with the treatment liquid. In other words, the treatment liquid removes the replacement liquid from the substrate W. Then, the pump 33 stops. The valve 18a closes. The first nozzle 15a stops supplying the treatment liquid.

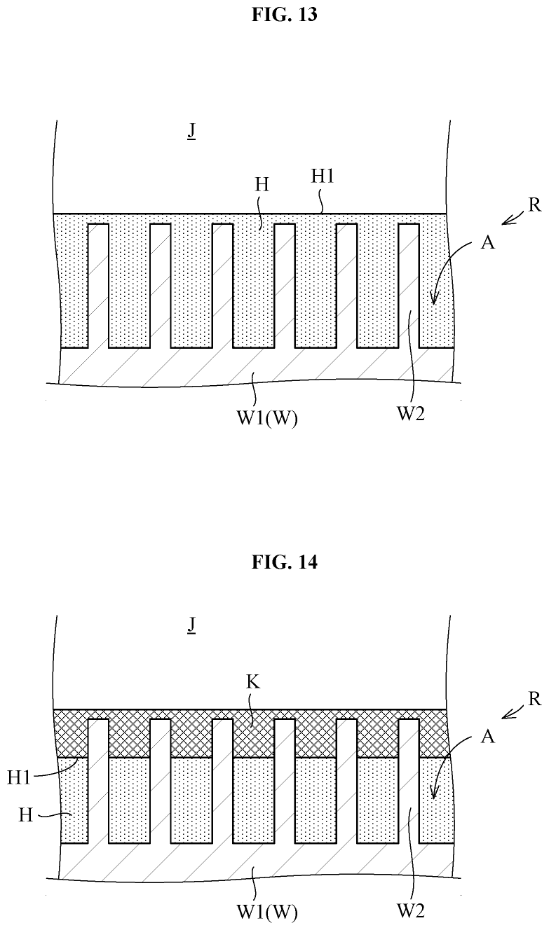

FIG. 13 schematically shows the substrate W in the treatment liquid supplying step. The substrate W has a pattern R. The pattern R is formed on a surface of the substrate W. When the substrate W is held by the substrate holder 13, the pattern R is positioned on the upper surface W1 of the substrate W. When the substrate W is held by the substrate holder 13, the pattern R is directed upward.

The pattern R may be formed before the treating unit 11 treats the substrate W, for example. The pattern R may be formed in the chemical liquid supplying step (Step S12), for example.

The pattern R includes projections W2 and recesses A. The projections W2 are part of the substrate W. The projections W2 are a structure. The projections W2 are each formed with a silicon oxide (SiO₂) film, a silicon nitride (SiN) film, or a polysilicon film, for example. The projections W2 project upward. The recess A is laterally adjacent to the projection W2. The recess A is a space. The recess A is opened upward. The projection W2 corresponds to a wall defining the recess A.

A treatment liquid H is positioned above the upper surface W1 of the substrate W. The treatment liquid H forms a film that covers the upper surface W1 of the substrate W.

The treatment liquid H has a top face H1. The top face H1 is positioned higher in level than the entire of the pattern R. The pattern R is entirely immersed in the treatment liquid H. The top face H1 is positioned higher in level than the entire of the projections W2. The projections W2 are entirely immersed in the treatment liquid H.

The recesses A are filled with the treatment liquid H. The recesses A are entirely filled only with the treatment liquid H.

Here, the replacement liquid has already been removed from the upper surface W1 of the substrate W by the treatment liquid H. Consequently, there is no replacement liquid on the upper surface W1 of the substrate W. No replacement liquid remains in the recesses A.

Gas J exists above the treatment liquid H. The gas J contacts the top face H1. The top face H1 corresponds to a gas-liquid interface between the treatment liquid H and the gas J. The projections W2 do not contact the top face H1. Accordingly, the treatment liquid H forms no meniscus relative to the projections W2. Consequently, no surface tension of the treatment liquid H acts on the projections W2.

In the treatment liquid supplying step, a height position of the top face H1 of the treatment liquid H may be adjusted additionally. The height position of the top face H1 corresponds to a film thickness of the treatment liquid H. For example, the height position of the top face H1 may be adjusted while the first nozzle 15a supplies the treatment liquid H to the substrate W. For example, the height position of the top face H1 may be adjusted after the first nozzle 15a stops supplying the treatment liquid H to the substrate W. For example, the height position of the top face H1 may be adjusted by adjusting a rotation speed of the substrate W. For example, the height position of the top face H1 may be adjusted by adjusting a rotation time of the substrate W.

### Step S16: Solidified Film Forming Step

The solvent and the surfactant each evaporates from the treatment liquid H on the substrate W1. The solvent and the surfactant each change from liquid to gas. Since the solvent and the surfactant evaporate, the solvent and the surfactant are each removed from the substrate W. Evaporation of the solvent and the surfactant causes deposition of the sublimable substance on the substrate W. A solidified film is formed on the substrate W. The solidified film is formed on the upper surface W1 of the substrate W. The solidified film contains the deposited sublimable substance. The solidified film does not contain the solvent or the surfactant. The solidified film is solid.

FIG. 14 schematically shows the substrate W in the solidified film forming step. As the solvent and the surfactant evaporate from the treatment liquid H, the sublimable substance is deposited and a solidified film K is formed. The solvent and the surfactant contained in the treatment liquid H are each removed from the upper surface W1 of the substrate W, and the sublimable substance contained in the treatment liquid H is changed into the solidified film K.

As described above, the treatment liquid satisfies the third condition F3. That is, the vapor pressure Pb of the solvent at room temperature is higher than the vapor pressure Pa of the sublimable substance at room temperature. Accordingly, the solvent evaporates more easily than the sublimable substance. As a result, the solidified film K is formed suitably.

In addition, the treatment liquid satisfies the fourth condition F4. That is, the vapor pressure Pc of the surfactant at room temperature is higher than the vapor pressure Pa of the sublimable substance at room temperature. Accordingly, the surfactant evaporates more easily than the sublimable substance. As a result, the solidified film K is formed more suitably.

The treatment liquid H gradually changes into the solidified film K. Firstly, an upper part of the treatment liquid H changes into the solidified film K. The solidified film K is formed above the top face H1 of the treatment liquid H. The solidified film K covers the top face H1 of the treatment liquid H. The height position of the top face H1 of the treatment liquid H is gradually lowered. The remaining treatment liquid H is positioned below the solidified film K.

After the solidified film K covers the top face H1 of the treatment liquid H, the top face H1 of the treatment liquid H does not contact the gas J. That is, the treatment liquid H does not contact the gas J. The top face H1 is covered with the solidified film K, whereby a gas-liquid interface between the treatment liquid H and the gas J disappears. The top face H1 contacts the solidified film K. The gas J contacts the solidified film K. Accordingly, the treatment liquid H is reduced in the solidified film forming step without applying any significant force to the projections W2. The solvent and the surfactant are removed from the substrate W without applying any significant force to the projections W2.

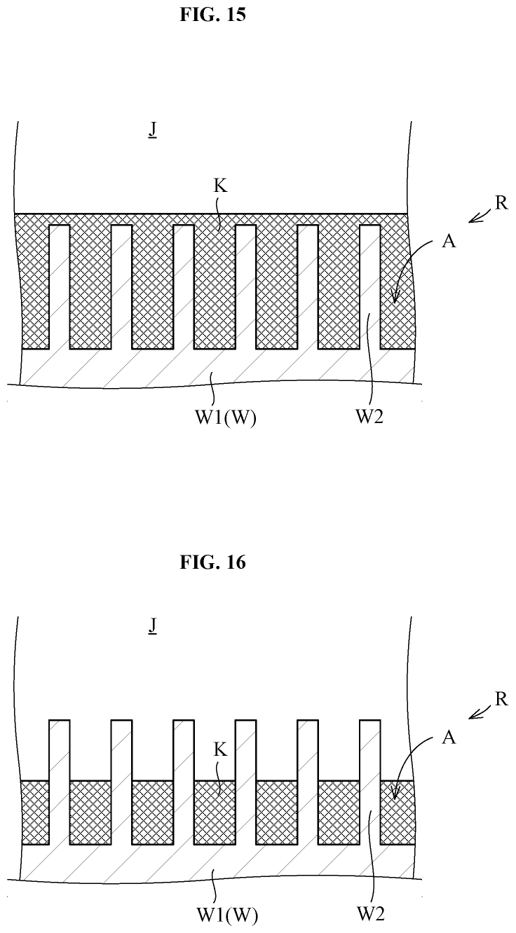

FIG. 15 schematically shows the substrate W in the solidified film forming step. Finally, the treatment liquid H entirely disappears from the substrate W. There exists no liquid on the upper surface W1 of the substrate W. The treatment liquid H does not remain in the recesses A when the solidified film forming step is completed. The recesses A are filled with the solidified film K. The recesses A are entirely filled only with the solidified film K. No liquid exists in the recesses A. The pattern R contacts the solidified film K. The pattern R does not contact the liquid. The projections W2 contact the solidified film K. The projections W2 do not contact any liquid.

### Step S17: Sublimation Step

In the sublimation step, the solidified film K sublimates. Specifically, the valve 18e opens. The fifth nozzle 15e supplies gas to the substrate W held by the substrate holder 13. The fifth nozzle 15e blows the gas onto the upper surface W1 of the substrate W. The fifth nozzle 15e supplies the gas to the solidified film K on the substrate W. The solidified film K sublimates. The solidified film K changes from solid to gas without being a liquid. Such sublimation of the solidified film K causes the solidified film K to be removed from the substrate W. Then, the valve 18e closes. The fifth nozzle 15e stops supplying the gas.

FIG. 16 schematically shows the substrate W in the sublimation step. The solidified film K is gradually reduced as the solidified film K sublimates, and gas J enters into the recesses A.

When the solidified film K sublimates, the solidified film K does not change into liquid. Accordingly, there exists no liquid on the upper surface W1 of the substrate W in the sublimation step. No liquid exists in the recesses A. The pattern R does not contact any liquid. The projections W2 do not contact any liquid. The solidified film K is removed from the upper surface W1 of the substrate W without applying any significant force to the projections W2.

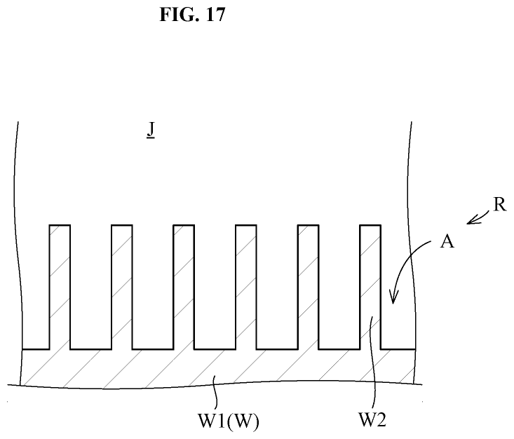

FIG. 17 schematically shows the substrate W in the sublimation step. Finally, the solidified film K disappears from the upper surface W1 of the substrate W. The recesses A are filled with the gas J. The recesses A are entirely filled only with the gas J. There exists no liquid on the upper surface W1 of the substrate W. The substrate W is dried completely.

The treatment liquid supplying step, the solidified film forming step, and the sublimation step corresponds to an example of using the treatment liquid. The treatment liquid is used under an environment of room temperature. The treatment liquid is used under an environment of normal pressure.

### Step S18: Rotation Stopping Step

The rotation driving unit 14 stops rotating the substrate holder 13. The substrate W held by the substrate holder 13 stops rotation. The substrate W rests. The treating unit 11 completes treatment on the substrate W.

### <1-6. Technical Meanings of First Condition F1 and Second Condition F2>

The following describes technical meanings of the first condition F1 and the second condition F2 from experimental examples 1 and 2 and comparative examples 1 to 3.

The experimental example 1 is executed under conditions as below. In the experimental example 1, a series of treatment is performed on the substrate W, the series including the chemical liquid supplying step, a rinse liquid supplying step, a replacement liquid supplying step, a treatment liquid supplying step, a solidified film forming step, and a sublimation step. In the chemical liquid supplying step, hydrofluoric acid is used as a chemical liquid. In the rinse liquid supplying step, deionized water (DIW) is used as a rinse liquid. In the replacement liquid supplying step, isopropyl alcohol is used as a replacement liquid.

In the treatment liquid supplying step, a plurality of types of treatment liquids having different amounts of surfactant added therein are prepared. Specifically, a surfactant-free liquid is generated. The surfactant-free liquid contains a sublimable substance, and a solvent, and does not contain a surfactant. The surfactant-free liquid consists of only a sublimable substance and a solvent, for example. The sublimable substance is cyclohexanone oxime. The solvent is isopropyl alcohol (IPA). A volume ratio of the sublimable substance and the solvent is as under.

Sublimable substance: Solvent=2.5:100 (volume ratio)

Next, a surfactant is added to the surfactant-free liquid to generate a treatment liquid. Specifically, an additive amount of the surfactant is changed to generate a plurality of types of treatment liquids.

In the present specification, an additive amount T of the surfactant is defined with reference to a volume of the solvent. Specifically, the additive amount T of the surfactant is defined as under:

Additive amount T=(volume of the surfactant contained in the treatment liquid)/(volume of the solvent contained in the treatment liquid)*100 [vol %]

Here, 100 vol % corresponds to a volume of the solvent in the treatment liquid.

The additive amount T of the surfactant in the surfactant-free liquid is 0.00.

Then, eight types of treatment liquids are prepared. The eight types of treatment liquids have different additive amounts T of the surfactant. The additive amounts T of the surfactant in the treatment liquids are 0.01, 0.05, 0.10, 0.50, 1.00, 2.00, 5.00, and 10.00.

In the experimental example 1, the surfactant is tert-butanol. Accordingly, in the experimental example 1, the treatment liquid contains cyclohexanone oxime as the sublimable substance, isopropyl alcohol (IPA) as the solvent, and tert-butanol as the surfactant.

The treatment liquid in the experimental example 1 corresponds to the treatment liquid of No. 5 shown in FIG. 4. In other words, the treatment liquid in the experimental example 1 corresponds to a treatment liquid containing cyclohexanone oxime, and the solvent and the surfactant defined in the feature a5).

In the treatment liquid supplying step, any one type of the treatment liquids is used. Accordingly, in the experimental example 1, the series of treatment is performed on substrates W at times same as the number of types of the treatment liquids. Then, a plurality of substrates W are obtained on which the series of treatment is performed for each type of the treatment liquids.

On the other hand, in the treatment liquid supplying step, the series of treatment is performed on a substrate W with use of a surfactant-free liquid instead of the treatment liquid.

The experimental example 2 is executed under conditions as below. The surfactant is methanol. The conditions other than the above are the same as those of the experimental example 1.

The treatment liquid in the experimental example 2 corresponds to the treatment liquid of No. 3 shown in FIG. 4. In other words, the treatment liquid in the experimental example 2 corresponds to a treatment liquid containing cyclohexanone oxime, and the solvent and the surfactant defined in the feature a3).

The comparative example 1 is executed under conditions as below. The surfactant is cyclohexane. The conditions other than the above are the same as those of the experimental example 1.

The treatment liquid in the comparative example 1 satisfies the second condition F2, the third condition F3, and the fourth condition F4, but does not satisfy the first condition F1. When the surfactant is cyclohexane, an octanol-water partition coefficient LOGPow of the surfactant is more than 1. Specifically, the cyclohexane has an octanol-water partition coefficient LOGPow of approximately 3.

The comparative example 2 is executed under conditions as below. The surfactant is acetone. The conditions other than the above are the same as those of the experimental example 1.

The treatment liquid in the comparative example 2 satisfies the first condition F1, the third condition F3, and the fourth condition F4, but does not satisfy the second condition F2. When the solvent is isopropyl alcohol (IPA) and the surfactant is acetone, vapor pressure Pc of the surfactant at room temperature is more than 3 times of vapor pressure Pb of the solvent at room temperature. Specifically, vapor pressure Pb of isopropyl alcohol (IPA) at room temperature is 4.4 kPa. Vapor pressure Pc of acetone at room temperature is 24 kPa. The vapor pressure Pc of the acetone at room temperature is approximately five times the vapor pressure Pb of the isopropyl alcohol (IPA) at room temperature.

The comparative example 3 is executed under conditions as below. The surfactant is 1-butanol. The conditions other than the above are the same as those of the experimental example 1.

The treatment liquid in the comparative example 3 satisfies the first condition F1, the third condition F3, and the fourth condition F4, but does not satisfy the second condition F2. When the solvent is isopropyl alcohol (IPA) and the surfactant is 1-butanol, vapor pressure Pc of the surfactant at room temperature is less than 0.9 times of vapor pressure Pb of the solvent at room temperature. Specifically, vapor pressure Pb of isopropyl alcohol (IPA) at room temperature is 4.4 kPa. Vapor pressure Pc of 1-butanol at room temperature is 0.7 kPa. Accordingly, the vapor pressure Pc of the 1-butanol at room temperature is approximately 0.2 times the vapor pressure Pb of the isopropyl alcohol (IPA) at room temperature.

Substrates W treated in the experimental examples 1 and 2 and the comparative examples 1 to 3 are individually evaluated under the following evaluation criterions. An observer observes measurement points on a substrate W. Here, each measurement point is a minute region of any position on the substrate W. Each measurement point is magnified 50,000 times by a scanning electron microscopy. The observer counts the number N of projections W2 and the number n of collapsed projections W2 at each measurement point. Here, the number n is equal to or less than the number N. The observer calculates a collapse rate at each measurement point. In addition, the observer calculates an average value of the collapse rates for each of the substrates W.

The collapse rate is defined by the numbers N and n as follows:

(Collapse rate at each measurement point)=n/N*100(%)

The average value (%) of the collapse rates is obtained by dividing the sum of the collapse rates at each measurement point by the number of measurement points.

In addition, an index number of collapse is calculated from the following mathematical expression:

Index number of collapse=(average value of collapse rates)/(average value of collapse rates in use of surfactant-free liquid)

Specifically, an index number of collapse is calculated from the following mathematical expression:

Index number of collapse=(average value of collapse rates in use of treatment liquid)/(average value of collapse rates in use of surfactant-free liquid)

Index number of collapse of less than 1 means that a collapse rate is improved from the collapse rate in use of the surfactant-free liquid. That is, when the index number of collapse is less than 1, the collapse rate of the pattern R is considered suppressed. Index number of collapse of more than 1 means that a collapse rate is deteriorated from the collapse rate in use of the surfactant-free liquid. That is, when the index number of collapse is more than 1, the collapse rate of the pattern R is considered increased.

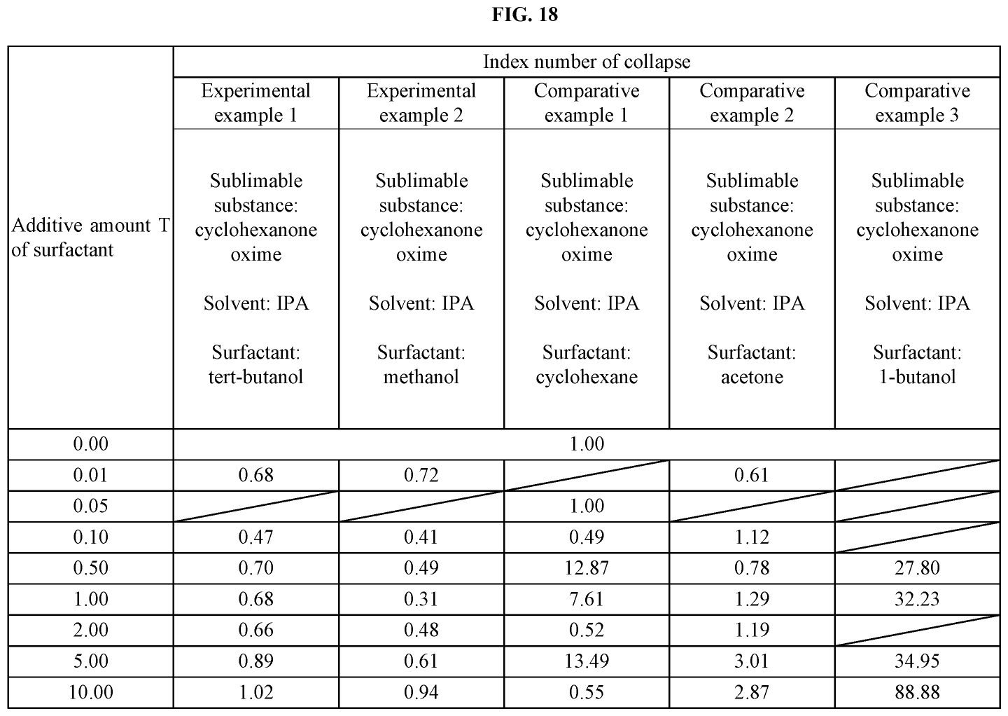

FIG. 18 is a table showing evaluations of each substrate W treated in the experimental examples 1 and 2 and the comparative examples 1 to 3. Specifically, FIG. 18 shows a relationship between the additive amount T of the surfactant and the index number of collapse.

In the experimental example 1, an index number of collapse with the additive amount T of 0.01 vol % to 10 vol % is substantially less than 1. Accordingly, the collapse rate of the pattern R is suppressed in the experimental example 1. The index number of collapse is decreased as the additive amount T is increased in a range of the additive amount T between 0.01 vol % and 0.1 vol %. The index number of collapse is increased as the additive amount T is increased in a range of the additive amount T between 0.1 vol % and 10 vol %. When the additive amount T is 0.1 vol %, the index number of collapse is 0.47. Here, the value 0.47 is the minimum value of the index number of collapse in the experimental example 1.

In the experimental example 2, an index number of collapse with the additive amount T of 0.01 vol % to 10 vol % is less than 1. Accordingly, the collapse rate of the pattern R is suppressed in the experimental example 2. The index number of collapse is decreased as the additive amount T is increased in a range of the additive amount T between 0.01 vol % and 1.0 vol %. The index number of collapse is increased as the additive amount T is increased in a range of the additive amount T between 1.0 vol % and 10 vol %. When the additive amount T is 1.0 vol %, the index number of collapse is 0.31. Here, the value 0.31 is the minimum value of the index number of collapse in the experimental example 2.

In the comparative example 1, the index number of collapse is significantly large in half or more of a range of the additive amount T between 0.05 vol % and 10 vol %. Accordingly, the collapse rate of the pattern R is deteriorated in the comparative example 1. In the comparative example 1, the index number of collapse is repeatedly increased and decreased between less than 1 and significantly more than 1 when the additive amount T falls within a range of 0.05 vol % to 10 vol %.

In the comparative example 2, the index number of collapse is more than 1 in most of a range of the additive amount T between 0.01 vol % and 10 vol %. Accordingly, the collapse rate of the pattern R is deteriorated in the comparative example 2. The index number of collapse is repeatedly increased and decreased between less than 1 and more than 1 when the additive amount T falls within a range of 0.01 vol % to 0.1 vol %. The index number of collapse is significantly large when the additive amount T falls within a range of 5 vol % to 10 vol %.

In the comparative example 3, the index number of collapse is significantly larger than 1 when the additive amount T falls within a range of 0.50 vol % to 10 vol %. Accordingly, the collapse rate of the pattern R is deteriorated in the comparative example 3.

### <1-7. Relationship Between First Condition F1 and Drying of Substrate W>

As shown in the comparative example 1, the collapse rate of the pattern R is increased when the surfactant has an octanol-water partition coefficient LOGPow of more than 1. The Inventors assume that such a phenomenon is caused by an excessive thick liquid film of the treatment liquid when the treatment liquid supplying step is completed. Hereinafter, description will be made for a possible mechanism in the comparative example 1.

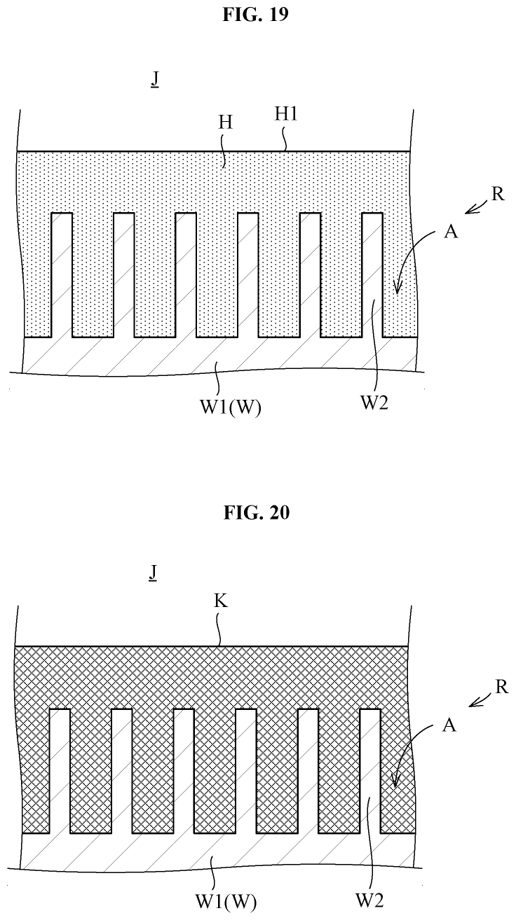

FIGS. 19, 20, and 21 each exemplarily show a mechanism for collapse of the pattern R. FIG. 19 schematically shows the substrate W in the treatment liquid supplying step. FIG. 20 schematically shows the substrate W in the solidified film forming step. FIG. 21 schematically shows the substrate W in the sublimation step. FIGS. 19 to 21 each illustrate the comparative example 1. FIGS. 19 to 21 each illustrate a case where the surfactant has an octanol-water partition coefficient LOGPow of more than 1.

Reference is made to FIG. 19. When the surfactant has an octanol-water partition coefficient LOGPow of more than 1, the treatment liquid H has strong hydrophobicity. The projections W2 have hydrophobicity. Accordingly, affinity between the treatment liquid H and the substrate W is excessively high. Accordingly, a film thickness of the treatment liquid H formed on the substrate W easily becomes excessively large in the treatment liquid supplying step. For example, a film thickness of the treatment liquid H easily becomes excessively larger than a height of the pattern R. For example, a film thickness of the treatment liquid H easily becomes excessively larger than a height of the projection W2.

Moreover, affinity between the treatment liquid H and the substrate W is high. Accordingly, it is hard to make the film thickness of the treatment liquid H thinner in the treatment liquid supplying step. It is hard to adjust the film thickness of the treatment liquid H in the treatment liquid supplying step.

Reference is made to FIG. 20. Accordingly, a film thickness of the solidified film K formed on the substrate W easily becomes excessively large in the solidified film forming step. For example, a film thickness of the solidified film K easily becomes excessively larger than the height of the pattern R. For example, a film thickness of the solidified film K easily becomes excessively larger than the height of the projection W2.

Reference is made to FIG. 21. This results in collapse of the projections W2 (pattern R) in the sublimation step when the solidified film K sublimates. For example, two adjacent projections W2 are attached to each other.

On the other hand, the collapse rate of the pattern R is considered high also when the surfactant has an octanol-water partition coefficient LOGPow of less than −1. The Inventors assume that such a phenomenon is caused by the replacement liquid remaining in the recesses A when the treatment liquid supplying step is completed. Hereinafter, description will be made for a possible mechanism in the case where the surfactant has an octanol-water partition coefficient LOGPow of less than −1.

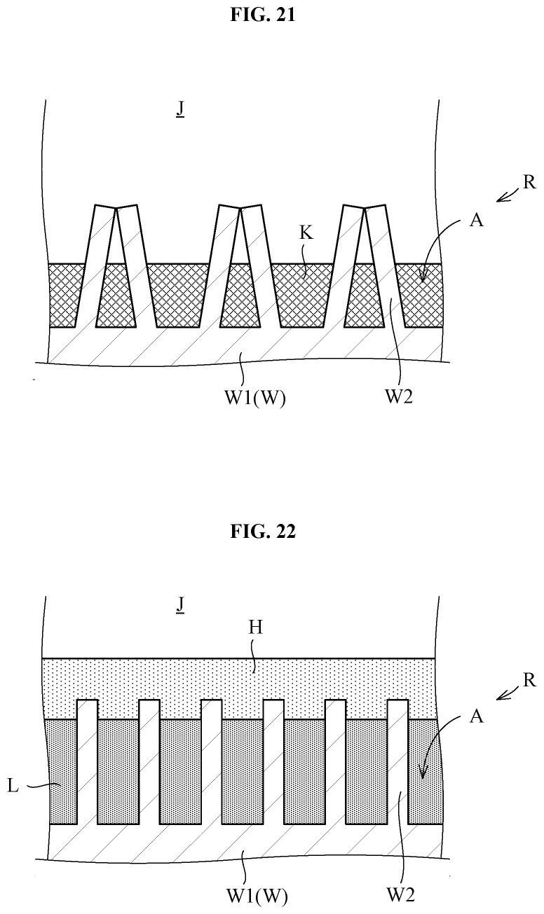

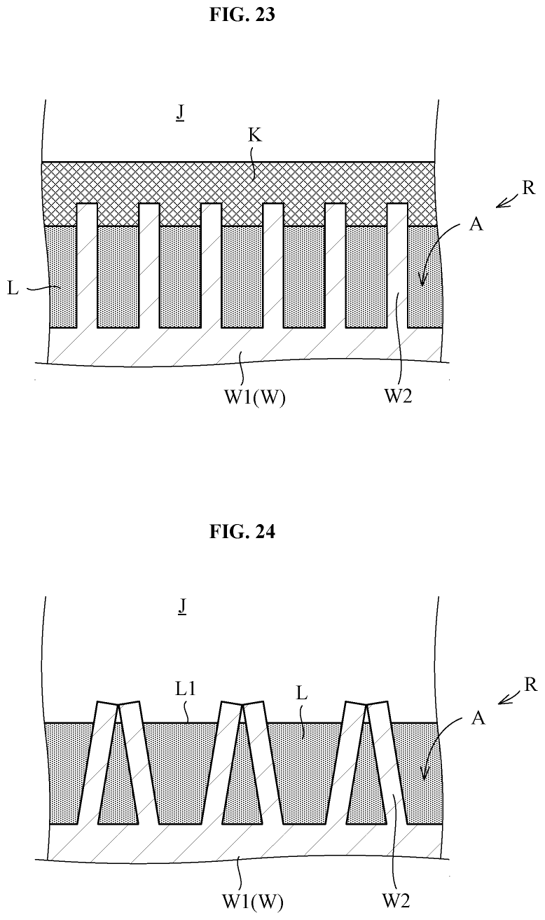

FIGS. 22, 23, and 24 each exemplarily show a mechanism for collapse of the pattern R. FIG. 22 schematically shows the substrate W in the treatment liquid supplying step. FIG. 23 schematically shows the substrate W in the solidified film forming step. FIG. 24 schematically shows the substrate W in the sublimation step. FIGS. 22 to 24 each illustrate a case where the surfactant has an octanol-water partition coefficient LOGPow of less than −1.

Reference is made to FIG. 22. When the surfactant has an octanol-water partition coefficient LOGPow of less than −1, the treatment liquid H has strong hydrophilicity. As described above, the projections W2 have hydrophobicity. Accordingly, affinity between the treatment liquid H and the substrate W is excessively low. Accordingly, the treatment liquid H is hard to enter the recesses A satisfactorily, for example. For example, the treatment liquid H cannot remove the replacement liquid L from the substrate W satisfactorily. As a result, when the treatment liquid supplying step is completed, the replacement liquid L remains in the recesses A in the form of liquid. Even when the treatment liquid supplying step is completed, the recesses A are not entirely filled only with the treatment liquid H.

Reference is made to FIG. 23. As a result, in the solidified film forming step, the recesses A are not entirely filled only with the solidified film K. In other words, the solidified film K is not formed on the entire of the recesses A. Even when the solidified film forming step is completed, the replacement liquid L remains in the recesses A in the form of liquid.

Reference is made to FIG. 24. In the sublimation step, the solidified film K sublimates. The replacement liquid L remains in the recesses A even after the solidified film K sublimates. The replacement liquid L has a top face L1. After the solidified film K sublimates, the top face L1 is to contact gas J. The top face L1 corresponds to a gas-liquid interface between the replacement liquid L and the gas J. The top face L1 contacts the projections W2. Accordingly, the replacement liquid L forms meniscus relative to the projections W2. Consequently, a surface tension of the replacement liquid L acts on the projections W2. The replacement liquid L applies a significant force to the projections W2. This results in collapse of the projections W2 (pattern R).

As described above, the collapse rate of the pattern R is not suppressed even in both cases where the surfactant has an octanol-water partition coefficient LOGPow of more than 1 and that of less than −1. Rather, the collapse of the pattern R is deteriorated. Consequently, a substrate W cannot be dried suitably when the treatment liquid H does not satisfy the first condition F1.

In contrast to this, the treatment liquid H satisfies the first condition F1 in the experimental examples 1 and 2 as described above. Accordingly, the treatment liquid H has suitable affinity to the substrate W. Consequently, the collapse rate of the pattern R is suppressed suitably in the experimental examples 1 and 2. That is, the substrate W can be dried appropriately while the pattern R is protected in the experimental examples 1 and 2.

More specifically, the surfactant has amphiphilicity when the surfactant has an octanol-water partition coefficient LOGPow of −1 or more and 1 or less. That is, the surfactant has both hydrophobicity and hydrophilicity. Accordingly, the surfactant has affinity relative to the substrate W and affinity relative to the sublimable substance. For example, the affinity between the surfactant and the substrate W is higher than the affinity between the sublimable substance and the substrate W. For example, the affinity between the surfactant and the sublimable substance is higher than the affinity between the sublimable substance and the substrate W. Accordingly, the affinity between the sublimable substance and the substrate W is enhanced via the surfactant. As a result, the treatment liquid H has suitable affinity to the substrate W.

### <1-8. Relationship Between Second Condition F2 and Drying of Substrate W>

As shown in the comparative example 2, the collapse rate of the pattern R is increased when the vapor pressure Pc of the surfactant at room temperature is more than 3 times of the vapor pressure Pb of the solvent at room temperature. The Inventors assume that such a phenomenon is caused by the replacement liquid L remaining in the recesses A when the treatment liquid supplying step is completed. The following describes a possible mechanism in the case where the vapor pressure Pc of the surfactant at room temperature is more than 3 times of the vapor pressure Pb of the solvent at room temperature.

Reference is made to FIG. 22 for convenience. The surfactant has excessively high vapor pressure Pc. Specifically, the vapor pressure Pc of the surfactant at room temperature is more than 3 times of the vapor pressure Pb of the solvent at room temperature. Accordingly, the surfactant starts evaporating immediately after the treatment liquid H is supplied to the substrate W in the treatment liquid supplying step. The surfactant possibly does not remain in the treatment liquid H before the treatment liquid H sufficiently contacts the substrate W. The surfactant may evaporates before the treatment liquid H sufficiently contacts the substrate W. The affinity between the treatment liquid H and the substrate W is possibly decreased significantly before the treatment liquid H sufficiently contacts the substrate W. Accordingly, the treatment liquid H cannot remove the replacement liquid L from the substrate W satisfactorily. When the treatment liquid supplying step is completed, the replacement liquid L remains in the recesses A in the form of liquid. Even when the treatment liquid supplying step is completed, the recesses A are not entirely filled only with the treatment liquid H.

Reference is made to FIG. 23 for convenience. As a result, in the solidified film forming step, the recesses A are not entirely filled only with the solidified film K. Even when the solidified film forming step is completed, the replacement liquid L remains in the recesses A in the form of liquid.

Reference is made to FIG. 24 for convenience. The replacement liquid L remains in the recesses A even after the solidified film K sublimates. The top face L1 corresponds to a gas-liquid interface between the replacement liquid L and the gas J. The top face L1 contacts the projections W2. Consequently, a surface tension of the replacement liquid L acts on the projections W2. This results in collapse of the projections W2 (pattern R).

As shown in the comparative example 3, the collapse rate of the pattern R is increased when the vapor pressure Pc of the surfactant at room temperature is less than 0.9 times of the vapor pressure Pb of the solvent at room temperature. The Inventors assume that such a phenomenon is caused by the treatment liquid H remaining in the recesses A when the solidified film forming step is completed. The following describes a possible mechanism in the case where the vapor pressure Pc of the surfactant at room temperature is less than 0.9 times of the vapor pressure Pb of the solvent at room temperature.

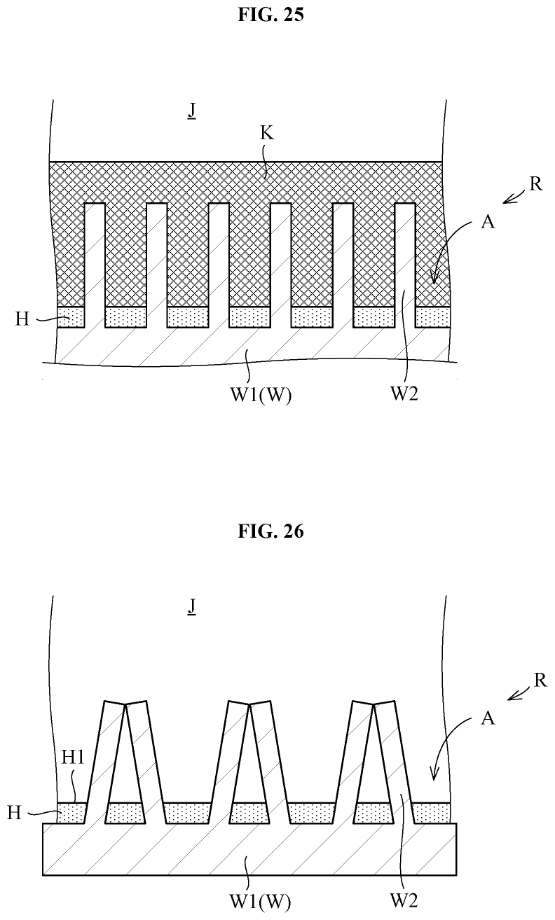

FIGS. 25 and 26 each exemplarily show a mechanism for collapse of the pattern R. FIG. 25 schematically shows the substrate W in the solidified film forming step. FIG. 26 schematically shows the substrate W in the sublimation step. FIGS. 25 and 26 each illustrate the comparative example 3. FIGS. 25 and 26 each illustrate a case where the vapor pressure Pc of the surfactant is excessively low. Specifically, the vapor pressure Pc of the surfactant at room temperature is less than 0.9 times of the vapor pressure Pb of the solvent at room temperature in FIGS. 25 and 26.

It is assumed that no replacement liquid L remains in the recesses A when the treatment liquid supplying step is completed. In this case, when the treatment liquid supplying step is completed, the recesses A are entirely filled only with the treatment liquid H (see FIG. 13).

Reference is made to FIG. 25. The solvent evaporates from the treatment liquid H in the solidified film forming step. However, the surfactant contained in the treatment liquid H hardly evaporates. This is because the vapor pressure Pc of the surfactant is excessively low. The treatment liquid H containing the surfactant remains in the recesses A even after all the solvent contained in the treatment liquid H evaporates completely. As a result, the treatment liquid H remains in the recesses A when the solidified film forming step is completed. The solidified film K is not formed on the entire of the recesses A.

Reference is made to FIG. 26. In the sublimation step, the solidified film K sublimates. The treatment liquid H remains in the recesses A even after the solidified film K sublimates. After the solidified film K sublimates, the top face H1 of the treatment liquid H contacts gas J. After the solidified film K sublimates, the top face H1 becomes a gas-liquid interface between the treatment liquid H and the gas J. The top face H1 contacts the projections W2. Accordingly, the treatment liquid H forms a meniscus relative to the projections W2. Consequently, a surface tension of the treatment liquid H acts on the projections W2. The treatment liquid H applies a significant force to the projections W2. This results in collapse of the projections W2 (pattern R).

As described above, collapse of the pattern R is not suppressed when the vapor pressure Pc of the surfactant at room temperature is more than 3 times of the vapor pressure Pb of the solvent at room temperature. Rather, the collapse of the pattern R is deteriorated. Also, collapse of the pattern R is not suppressed when the vapor pressure Pc of the surfactant at room temperature is less than 0.9 times of the vapor pressure Pb of the solvent at room temperature. Rather, the collapse of the pattern R is deteriorated. Consequently, a substrate W cannot be dried suitably when the treatment liquid H does not satisfy the second condition F2.

In contrast to this, the treatment liquid H satisfies the second condition F2 in the experimental examples 1 and 2 as described above. Accordingly, the surfactant has moderate vapor pressure Pc. Consequently, the collapse rate of the pattern R is suppressed suitably in the experimental examples 1 and 2. That is, the substrate W can be dried appropriately while the pattern R is protected in the experimental examples 1 and 2.

### <1-9. Relationship Between Additive Amount T of Surfactant and Drying of Substrate W>

In the experimental example 1, an index number of collapse in a range of the additive amount T between 0.1 vol % and 10 vol % is also substantially less than 1. However, in the experimental example 1, the index number of collapse is increased as the additive amount T is increased in a range of the additive amount T between 0.1 vol % and 10 vol %. In the experimental example 2, an index number of collapse in a range of the additive amount T between 1.0 vol % and 10 vol % is also less than 1. However, in the experimental example 2, the index number of collapse is increased as the additive amount T is increased in a range of the additive amount T between 1.0 vol % and 10 vol %. The Inventors assume that such a phenomenon is caused by a slightly thick liquid film of the treatment liquid H when the treatment liquid supplying step is completed. Hereinafter, description will be made for a possible mechanism in the case where the additive amount T is increased.

Affinity between the treatment liquid H and the substrate W becomes high as the additive amount T is increased. Accordingly, a film thickness of the treatment liquid H formed in the treatment liquid supplying step becomes large as the additive amount T is increased. The film thickness of the treatment liquid H becomes hardly small as the additive amount T is increased. As a result, a film thickness of the solidified film K formed in the solidified film forming step becomes large as the additive amount T is increased. This results in slightly easy collapse of the projections W2 (pattern R) in the sublimation step when the solidified film K sublimates.

Consequently, it is preferred to select the additive amount T of the surfactant suitably. This makes it possible to suppress the collapse of the pattern R more suitably.

For example, it is preferred that the additive amount T of the surfactant is 10 vol % or less of the volume of the solvent contained in the treatment liquid H. In other words, it is preferred that the volume of the surfactant contained in the treatment liquid H is 10% or less of the volume of the solvent contained in the treatment liquid H.

On the other hand, the collapse of the pattern R is sufficiently suppressed even when the additive amount T of the surfactant is 0.01 vol % in the experimental examples 1 and 2. For example, an index number of collapse is 0.68 when the additive amount T of the surfactant is 0.01 vol % in the experimental example 1. For example, an index number of collapse is 0.72 when the additive amount T of the surfactant is 0.01 vol % in the experimental example 2.

Accordingly, it is preferred that the additive amount T of the surfactant is 0.01 vol % or more of the volume of the solvent contained in the treatment liquid H, for example. In other words, it is preferred that the volume of the surfactant contained in the treatment liquid H is 0.01% or more of the volume of the solvent contained in the treatment liquid H.

### <1-10. Effect of First Embodiment>

The substrate treating method includes the treatment liquid supplying step, the solidified film forming step, and the sublimation step. In the treatment liquid supplying step, the treatment liquid H is supplied to the substrates W. The treatment liquid H contains the sublimable substance, the solvent, and the surfactant. In the solidified film forming step, the solvent and the surfactant evaporate from the treatment liquid H on the substrate W. In the solidified film forming step, the solidified film K is formed on the substrate W. The solidified film K contains the sublimable substance. In the sublimation step, the solidified film K sublimates.

The treatment liquid H satisfies the first condition F1. Specifically, the surfactant has an octanol-water partition coefficient LOGPow of −1 or more and 1 or less. Accordingly, the treatment liquid H has suitable affinity to the substrate W. Accordingly, the surfactant enhances the affinity between the sublimable substance and the substrate W. As a result, the treatment liquid H can be supplied suitably to the substrate W in the treatment liquid supplying step. For example, in the treatment liquid supplying step, the treatment liquid H satisfactorily contacts the upper surface W1 of the substrate W. In other words, in the treatment liquid supplying step, the treatment liquid H is applied on the upper surface W1 of the substrate W satisfactorily. Even with the substrate W having the pattern R formed thereon, the treatment liquid H satisfactorily contacts the pattern R. For example, the treatment liquid H easily enters the recesses A. For example, the treatment liquid H suitably removes the replacement liquid L from the substrate W. Moreover, the film thickness of the treatment liquid H does not become excessively large. The film thickness of the treatment liquid H can be adjusted easily.

The treatment liquid satisfies the second condition F2. Specifically, vapor pressure Pc of the surfactant at room temperature is 0.9 times or more and 3 times or less vapor pressure Pb of the solvent at room temperature.

The vapor pressure Pc of the surfactant at room temperature is 3 times or less of the vapor pressure Pb of the solvent at room temperature. Accordingly, vapor pressure Pc of the surfactant at room temperature is not excessively high. As a result, the treatment liquid H can be supplied more suitably to the substrate W in the treatment liquid supplying step. For example, in the treatment liquid supplying step, the surfactant remains in the treatment liquid H without evaporating and causes the treatment liquid H to contact the substrate W satisfactorily. Accordingly, in the treatment liquid supplying step, the treatment liquid H contacts the substrate W satisfactorily and certainly. For example, the treatment liquid H can remove the replacement liquid L from the surface of the substrate W satisfactorily in the treatment liquid supplying step. For example, when the treatment liquid supplying step is completed, the treatment liquid H can suitably prevent the replacement liquid L from remaining in the recesses A.

In addition, the vapor pressure Pc of the surfactant at room temperature is 0.9 times or more of the vapor pressure Pb of the solvent at room temperature. Consequently, the vapor pressure Pc of the surfactant at room temperature is not excessively low. As a result, the surfactant evaporates suitably in the solidified film forming step. Since the surfactant evaporates suitably, the sublimable substance is deposited suitably. As a result, the solidified film K can be formed on the substrate W appropriately in the solidified film forming step. For example, the treatment liquid H can be suitably prevented from remaining in the recesses A when the solidified film forming step is completed. As a result, the pattern R can be protected suitably also in the sublimation step.

In summary, since the treatment liquid H satisfies the first condition F1 and the second condition F2, the treatment liquid H can be supplied suitably to the substrate W in the treatment liquid supplying step. Since the treatment liquid H satisfies the second condition, the solidified film K can be formed on the substrate W appropriately in the solidified film forming step. As a result, the substrate treating method according to the first embodiment achieves proper drying of substrates W.

The treatment liquid satisfies the third condition F3. Specifically, the vapor pressure Pb of the solvent at room temperature is higher than the vapor pressure Pa of the sublimable substance at room temperature. Accordingly, the solvent evaporates more easily than the sublimable substance. Since the solvent evaporates, the sublimable substance is deposited more suitably. As a result, the solidified film K can be formed on the substrate W more suitably in the solidified film forming step.

The treatment liquid satisfies the fourth condition F4. Specifically, the vapor pressure Pc of the surfactant at room temperature is higher than the vapor pressure Pa of the sublimable substance at room temperature. Accordingly, the surfactant evaporates more easily than the sublimable substance. Since the surfactant evaporates, the sublimable substance is deposited more suitably. As a result, the solidified film K can be formed on the substrate W more suitably in the solidified film forming step.

The treatment liquid H is used to dry the substrates W. The treatment liquid H contains the sublimable substance, the solvent, and the surfactant.

The treatment liquid H satisfies the first condition F1. Accordingly, the treatment liquid H has suitable affinity to the substrate W. Consequently, when the treatment liquid H is supplied to the substrate W, for example, the treatment liquid H satisfactorily contacts the substrate W.

The treatment liquid H satisfies the second condition F2. Accordingly, vapor pressure Pc of the surfactant at room temperature is not excessively high. Consequently, when the treatment liquid H is supplied to the substrate W, for example, the treatment liquid H contacts the substrate W satisfactorily and certainly. Moreover, the vapor pressure Pc of the surfactant at room temperature is not excessively low. As a result, the surfactant evaporates suitably. Since the surfactant evaporates suitably, the sublimable substance is deposited suitably, and the solidified film K is formed suitably.

As described above, the treatment liquid H satisfies the first condition F1 and the second condition F2. As a result, the treatment liquid H achieves suitable drying of the substrates W.

The treatment liquid H satisfies the third condition F3. Accordingly, the solvent evaporates more easily than the sublimable substance. Since the solvent evaporates, the sublimable substance is deposited more suitably, and the solidified film K is formed more suitably.

The treatment liquid H satisfies the fourth condition F4. Accordingly, the surfactant evaporates more easily than the sublimable substance. When the surfactant evaporates, the sublimable substance is deposited more suitably, and the solidified film K is formed more suitably.

For example, the sublimable substance is one selected from cyclohexanone oxime, camphor, and ε-caprolactam. The solvent and the surfactant correspond to one selected from the features a1) to a20) described above. The treatment liquid H satisfies the first condition F1 and the second condition F2 suitably when the sublimable substance, the solvent and the surfactant are specified as above. In other words, the treatment liquids H of Nos. 1 to 60 each satisfy the first condition F1 and the second condition F2 suitably. Accordingly, the substrate treating method can dry the substrates W suitably. The substrates W can be dried suitably with use of the treatment liquid H.

The treatment liquid H also satisfies the third condition F3 suitably when the sublimable substance, the solvent and the surfactant are specified as above. In other words, the treatment liquids H of Nos. 1 to 60 each also satisfy the third condition F3 suitably. Accordingly, the substrate treating method can dry the substrates W more suitably. The substrates W can be dried more suitably with use of the treatment liquid H.

The treatment liquid H also satisfies the fourth condition F4 suitably when the sublimable substance, the solvent and the surfactant are specified as above. In other words, the treatment liquids H of Nos. 1 to 60 each also satisfy the fourth condition F4 suitably. Accordingly, the substrate treating method can dry the substrates W more suitably. The substrates W can be dried more suitably with use of the treatment liquid H.

For example, the sublimable substance is at least one selected from cyclohexanone oxime, camphor, and ε-caprolactam, for example. The solvent and the surfactant correspond to one selected from the features b1) to b9) described above. The treatment liquid H satisfies the first condition F1 and the second condition F2 suitably when the sublimable substance, the solvent and the surfactant are specified as above. In other words, the treatment liquids H of Nos. 61 to 69 each satisfy the first condition F1 and the second condition F2 suitably. Accordingly, the substrate treating method can dry the substrates W suitably. The substrates W can be dried suitably with use of the treatment liquid H.

The treatment liquid H also satisfies the third condition F3 suitably when the sublimable substance, the solvent and the surfactant are specified as above. In other words, the treatment liquids H of Nos. 61 to 69 each also satisfy the third condition F3 suitably. Accordingly, the substrate treating method can dry the substrates W more suitably. The substrates W can be dried more suitably with use of the treatment liquid H.

The treatment liquid H also satisfies the fourth condition F4 suitably when the sublimable substance, the solvent and the surfactant are specified as above. In other words, the treatment liquids H of Nos. 61 to 69 each also satisfy the fourth condition F4 suitably. Accordingly, the substrate treating method can dry the substrates W more suitably. The substrates W can be dried more suitably with use of the treatment liquid H.

The sublimable substance is at least one selected from cyclohexanone oxime, camphor, and ε-caprolactam, for example. The solvent and the surfactant correspond to one selected from the features c1) to c9) described above. The treatment liquid H satisfies the first condition F1 and the second condition F2 suitably when the sublimable substance, the solvent and the surfactant are specified as above. In other words, the treatment liquids H of Nos. 70 to 78 each satisfy the first condition F1 and the second condition F2 suitably. Accordingly, the substrate treating method can dry the substrates W suitably. The substrates W can be dried suitably with use of the treatment liquid H.

The treatment liquid H also satisfies the third condition F3 suitably when the sublimable substance, the solvent and the surfactant are specified as above. In other words, the treatment liquids H of Nos. 70 to 78 each also satisfy the third condition F3 suitably. Accordingly, the substrate treating method can dry the substrates W more suitably. The substrates W can be dried more suitably with use of the treatment liquid H.

The treatment liquid H also satisfies the fourth condition F4 suitably when the sublimable substance, the solvent and the surfactant are specified as above. In other words, the treatment liquids H of Nos. 70 to 78 each also satisfy the fourth condition F4 suitably. Accordingly, the substrate treating method can dry the substrates W more suitably. The substrates W can be dried more suitably with use of the treatment liquid H.

The volume of the sublimable substance contained in the treatment liquid H is smaller than the volume of the solvent contained in the treatment liquid H. Accordingly, the substrate treating method can dry the substrates W more suitably. The substrates W can be dried more suitably with use of the treatment liquid H.

The volume of the sublimable substance contained in the treatment liquid H is 1% or more and 10% or less of the volume of the solvent contained in the treatment liquid H. Accordingly, the treatment liquid H contains a proper amount of the sublimable substance. Accordingly, the substrate treating method can dry the substrates W more suitably. The substrates W can be dried more suitably with use of the treatment liquid H.

The volume of the surfactant contained in the treatment liquid H is smaller than the volume of the solvent contained in the treatment liquid H. Accordingly, the substrate treating method can dry the substrates W more suitably. The substrates W can be dried more suitably with use of the treatment liquid H.

The volume of the surfactant contained in the treatment liquid H is 0.01% or more and 10% or less of the volume of the solvent contained in the treatment liquid H. That is, the additive amount T of the surfactant is 0.01% or more and 10 vol % or less with reference to the volume of the solvent in the treatment liquid H as 100 vol %. Accordingly, the treatment liquid H contains a proper amount of the surfactant. Consequently, the treatment liquid H has suitable affinity to the substrate W. Accordingly, the substrate treating method can dry the substrates W more suitably. The substrates W can be dried more suitably with use of the treatment liquid H.

The substrate W has the pattern R. The pattern R is formed on the surface of the substrate W. The pattern R is formed on the upper surface W1 of the substrate W. With the substrate treating method, the substrate W having the pattern R can be dried suitably while the pattern R is protected. For example, with the substrate treating method, the substrate W can be dried appropriately while collapse of the pattern R is suppressed.

The substrate treating apparatus 1 includes the substrate holder 13, the treatment liquid generating unit 20, and the first nozzle 15a. The substrate holder 13 holds a substrate W. The treatment liquid generating unit 20 generates the treatment liquid H. The first nozzle 15a supplies the treatment liquid H to the substrate W held by the substrate holder 13. The first nozzle 15a supplies the treatment liquid H, generated by the treatment liquid generating unit 20, to the substrate W held by the substrate holder 13.

Here, the treatment liquid H generated by the treatment liquid generating unit 20 satisfies the first condition F1 and the second condition F2. Consequently, the substrate treating apparatus 1 can perform the substrate treating method described above suitably. That is, the substrate treating apparatus 1 can dry substrates W appropriately.

The treatment liquid H generated by the treatment liquid generating unit 20 also satisfies the third condition F3. Accordingly, the substrate treating apparatus 1 can dry the substrates W more suitably.

The treatment liquid H generated by the treatment liquid generating unit 20 also satisfies the fourth condition F4. Accordingly, the substrate treating apparatus 1 can dry the substrates W more suitably.

The treatment liquid generating unit 20 includes the first tank 21. Accordingly, the treatment liquid generating unit 20 can generate the treatment liquid H suitably in the first tank 21.

Moreover, the treatment liquid generating unit 20 can store the treatment liquid H suitably in the first tank 21.

The substrate W held by the substrate holder 13 has the pattern R of the substrate W. The pattern R is formed on a surface of the substrate W. The pattern R is formed on the upper surface W1 of the substrate W held by the substrate holder 13. The substrate treating apparatus 1 can dry the substrate W suitably while the pattern R is protected even when the substrate W has the pattern R.

The substrate treating apparatus 1 includes the fifth nozzle 15e. The fifth nozzle 15e supplies gas to the substrate W held by the substrate holder 13. Accordingly, the substrate treating apparatus 1 can dry the substrate W effectively.

### 2. Second Embodiment

The following describes a substrate treating apparatus 1 according to a second embodiment with reference to drawings. Like numerals are used to identify like components which are the same as those in the first embodiment, and the components will not particularly be described.

The second embodiment has an outline of a substrate treating apparatus 1 and a construction of treating units 11 substantially same as those in the first embodiment. The following describes a construction of a treatment liquid generating unit 20 according to the second embodiment.

### <2-1. Construction of Treatment Liquid Generating Unit 20>

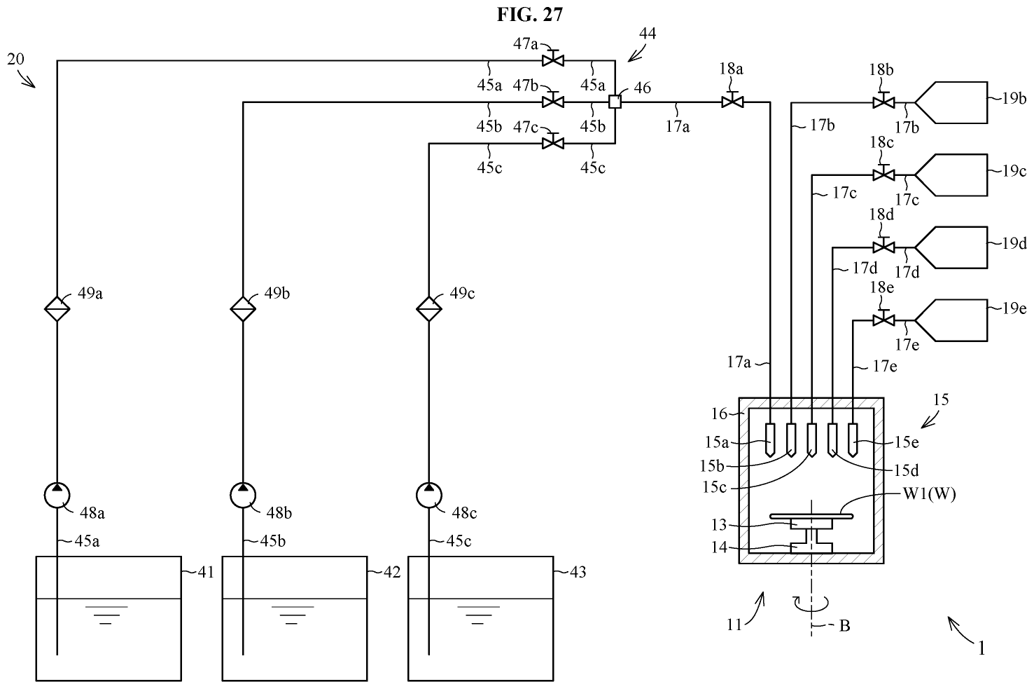

FIG. 27 shows a construction of a treating unit and the treatment liquid generating unit 20 according to the second embodiment. The treatment liquid generating unit 20 includes a first tank 41, a second tank 42, and a third tank 43. The first tank 41 stores a sublimable substance. For example, the first tank 41 may store a solvent together with the sublimable substance. The second tank 42 stores a solvent. For example, the second tank 42 stores only the solvent. The third tank 43 stores a surfactant. For example, the third tank 43 stores only the surfactant.

The treatment liquid generating unit 20 includes a mixing unit 44. The mixing unit 44 is in fluid communication with the first to third tanks 41 to 43. The mixing unit 44 is connected to the first to third tanks 41 to 43. The mixing unit 44 is also in fluid communication with the first nozzle 15a. The mixing unit 44 is connected to the first nozzle 15a. In the second embodiment, the treatment liquid generating unit 20 generates a treatment liquid in the mixing unit 44. Also in the second embodiment, the treatment liquid is generated under an environment of room temperature. The treatment liquid is generated under an environment of normal pressure.

The treatment liquid generated in the mixing unit 44 satisfies the first condition F1 and the second condition F2 described above. Moreover, the treatment liquid preferably satisfies the third condition F3. The treatment liquid preferably satisfies the fourth condition F4. The treatment liquid is any one selected from the treatment liquids of Nos. 1 to 78 shown in FIGS. 4 to 11, for example.

The mixing unit 44 includes pipes 45a, 45b, and 45c, and a joint 46. The pipe 45a is in fluid communication with the first tank 41 and the joint 46. The pipe 45a is connected to the first tank 41 and the joint 46. The pipe 45b is in fluid communication with the second tank 42 and the joint 46. The pipe 45b is connected to the second tank 42 and the joint 46. The pipe 45c is in fluid communication with the third tank 43 and the joint 46. The pipe 45c is connected to the third tank 43 and the joint 46. The joint 46 is also in fluid communication with the pipe 17a. The joint 46 is connected to the pipe 17a. The pipes 17a, 45a, 45b, and 45c are in fluid communication with one another through the joint 46.

The mixing unit 44 includes valves 47a, 47b, and 47c. The valves 47a, 47b, and 47c are provided on the pipes 45a, 45b, and 45c, respectively. The valve 47a regulates a flow rate of the sublimable substance that flows in the pipe 45a. The valve 47b regulates a flow rate of the solvent that flows in the pipe 45b. The valve 47c regulates a flow rate of the surfactant that flows in the pipe 45c. The valve 47a may include, for example, a flow rate regulating valve. The valve 47a may include, for example, a flow rate regulating valve and an on-off valve. The valves 47b and 47c may each be configured in the same manner as the valve 47a.

The mixing unit 44 includes pumps 48a, 48b, and 48c. The pumps 48a, 48b, and 48c are provided on the pipes 45a, 45b, and 45c, respectively. The pump 48a causes the sublimable substance to flow from the first tank 41 to the pipe 45a. The pump 48b causes the solvent to flow from the second tank 42 to the pipe 45b. The pump 48c causes the surfactant to flow from the third tank 43 to the pipe 45c.

The mixing unit 44 includes filters 49a, 49b, and 49c. The filters 49a, 49b, and 49c are provided on the pipes 45a, 45b, and 45c, respectively. The filer 49a filters the sublimable substance that flows in the pipe 45a. The filer 49b filters the solvent that flows in the pipe 45b. The filter 49c filters the surfactant that flows in the pipe 45c.

The controller 10 controls the mixing unit 44, which illustration is omitted. The controller 10 controls the valves 47a, 47b, and 47c, and the pumps 48a, 48b, and 48c.

### <2-2. Operation Example of Treatment Liquid Generating Unit 20 and Treating Unit 11>

Reference is made to FIG. 12. The substrate treating method according to the second embodiment includes a Step S1 and Steps S11 to S18, which is similar to the first embodiment. Operation in the Steps S11 to S14 and S16 to S18 are substantially common between the first embodiment and the second embodiment. Accordingly, description about the operation in the Steps S11 to S14 and S16 to S18 is to be omitted. The following describes operation in Steps S1 and S15.

### Steps S1, S15: Treatment Liquid Generating Step and Treatment Liquid Supplying Step

The treatment liquid generating unit 20 generates a treatment liquid in the mixing unit 44. The first nozzle 15a supplies the treatment liquid, generated in the treatment liquid generating unit 20, to the substrate W.

Specifically, the pump 48a feeds the sublimable substance from the first tank 41 to the joint 46 via the pipe 45a. The valve 47a regulates a flow rate of the sublimable substance to be supplied to the joint 46. The pump 48b feeds the solvent from the second tank 42 to the joint 46 via the pipe 45b. The valve 47b regulates a flow rate of the solvent to be supplied to the joint 46. The pump 48c feeds the surfactant from the third tank 43 to the joint 46 via the pipe 45c. The valve 47c regulates a flow rate of the surfactant to be supplied to the joint 46. The sublimable substance, the solvent, and the surfactant meet at the joint 46. The joint 46 generates the treatment liquid.

The valve 18a opens. The treatment liquid flows from the joint 46 to the first nozzle 15a through the pipe 17a. The first nozzle 15a supplies the treatment liquid to the substrate W held by the substrate holder 13. The first nozzle 15a dispenses the treatment liquid onto the upper surface W1 of the substrate W. The treatment liquid is supplied onto the upper surface W1 of the substrate W. As a result, the treatment liquid replaces the replacement liquid on the substrate W. Then, the pumps 48a, 48b, and 48c stop. The valves 18a, 47a, 47b, and 47c close. The first nozzle 15a stops supplying the treatment liquid.

### <2-3. Effect of Second Embodiment>

The second embodiment produces a similar effect to that of the first embodiment. For example, the treatment liquid satisfies the first condition F1 and the second condition F2. As a result, the substrate treating method according to the second embodiment can dry the substrates W suitably. The treatment liquid achieves suitable drying of the substrates W.

The treatment liquid generating unit 20 includes a mixing unit 44. Accordingly, the treatment liquid generating unit 20 can generate the treatment liquid suitably in the mixing unit 44.

The mixing unit 44 corresponds to a flow path in fluid communication with the first nozzle 15a. Accordingly, the treatment liquid generating unit 20 generates the treatment liquid in the flow path in fluid communication with the first nozzle 15a. Consequently, the treatment liquid generating unit 20 can generate the treatment liquid suitably when the first nozzle 15a is used for the treatment liquid. The first nozzle 15a can be used for the treatment liquid immediately after the treatment liquid generating unit 20 generates the treatment liquid.

This invention is not limited to the foregoing examples, but may be modified as follows.

(1) In the first and second embodiments, the treatment liquids of Nos. 1 to 78 shown in FIGS. 4 to 11 are exemplified. However, the present invention is not limited to this. Specifically, the treatment liquid may be one except the treatment liquids of Nos. 1 to 78.

(2) In the first and second embodiments, the sublimable substance contained in the treatment liquid is at least one selected from cyclohexanone oxime, camphor, and ε-caprolactam, for example. However, the present invention is not limited to this. Specifically, the sublimable substance may contain a substance except cyclohexanone oxime, camphor, and ε-caprolactam.

(3) In the first and second embodiments, the solvent and the surfactant contained in the treatment liquid correspond to any one selected from the features a1) to a20), b1) to b9), and c1) to c9), for example. However, the present invention is not limited to this. Specifically, the solvent and the surfactant contained in the treatment liquid may contain a substance except the substances defined in the features a1) to a20), b1) to b9), and c1) to c9).

(4) In the first and second embodiments, the substrate treating method includes the chemical liquid supplying step, the rinse liquid supplying step, and the replacement liquid supplying step. However, the present invention is not limited to this. For example, at least any of the chemical liquid supplying step, the rinse liquid supplying step, and the replacement liquid supplying step may be omitted. For example, all of the chemical liquid supplying step, the rinse liquid supplying step, and the replacement liquid supplying step may be omitted.

(5) In the first and second embodiments, a liquid (e.g., replacement liquid) exists on the substrate W when the treatment liquid supplying step is executed. That is, the treatment liquid is supplied to a non-dried substrate W in the treatment liquid supplying step. However, the present invention is not limited to this. For example, a liquid (e.g., replacement liquid) may not exist on the substrate W when the treatment liquid supplying step is executed. For example, the treatment liquid may be supplied to a dried substrate W in the treatment liquid supplying step.

(6) In the first and second embodiments, the replacement liquid is removed from the substrate W with the treatment liquid in the treatment liquid supplying step. However, the present invention is not limited to this. For example, the substrate W may be cleaned with the treatment liquid in the treatment liquid supplying step. For example, foreign substances attached to the substrate W may be removed with the treatment liquid in the treatment liquid supplying step. For example, foreign substances attached to the substrate W may be dissolved with the treatment liquid in the treatment liquid supplying step. The foreign substances are, for example, resist residual.

(7) In the first and second embodiments, gas is not supplied to the substrate W in the solidified film forming step. However, the present invention is not limited to this. Gas may be supplied to the substrate W in the solidified film forming step. Gas may be supplied to the treatment liquid on the substrate W in the solidified film forming step. This can form the solidified film on the substrate W effectively in the solidified film forming step.

(8) In the first embodiment, the sublimable substance supplying unit 23 may supply a sublimable substance in a liquid state to the first tank 21. For example, the sublimable substance supplying unit 23 may supply the sublimable substance together with the solvent to the first tank 21. Alternatively, the sublimable substance supplying unit 23 may supply a sublimable substance in a solid state to the first tank 21. For example, the sublimable substance supplying unit 23 may supply a sublimable substance in a powder state to the first tank 21. The sublimable substance supplying unit 23 may include a feeder configured to feed a sublimable substance in a solid state to the first tank 21. Likewise, in the second embodiment, the first tank 41 may store a sublimable substance in a liquid state or a sublimable substance in a solid state. When the first tank 41 stores a sublimable substance in a solid state, the mixing unit 44 may include a feeder configured to feed the solid sublimable substance from the first tank 41 to the joint 46.

(9) In the second embodiment, the first tank 41 stores the sublimable substance, the second tank 42 stores the solvent, and the third tank 43 stores the surfactant. However, the present invention is not limited to this. For example, any one of the first to third tanks 41 to 43 may store any two selected from the sublimable substance, the solvent, and the surfactant.

For example, the first tank 41 may store the solvent in addition to the sublimable substance. For example, the first tank 41 may store the surfactant-free liquid. The mixing unit 44 may add the surfactant, stored in the third tank 43, to the sublimable substance and the solvent stored in the first tank 41. The mixing unit 44 may mix the surfactant, supplied from the third tank 43, with the sublimable substance and the solvent supplied from the first tank 41. The second tank 42 is omittable in this modification.

For example, the first tank 41 may store the surfactant in addition to the sublimable substance. The mixing unit 44 may add the sublimable substance and the surfactant, stored in the first tank 41, to the solvent stored in the second tank 42. The mixing unit 44 may mix the sublimable substance and the surfactant, supplied from the first tank 41, with the solvent supplied from the second tank 42. The third tank 43 is omittable in this modification.

For example, the second tank 42 may store the surfactant in addition to the solvent. The mixing unit 44 may add the sublimable substance, stored in the first tank 41, to the solvent and the surfactant stored in the second tank 42. The mixing unit 44 may mix the sublimable substance, supplied from the first tank 41, with the solvent and the surfactant supplied from the second tank 42. The third tank 43 is omittable in this modification.

(10) In the first embodiment, the substrate treating apparatus 1 includes the first sensor 29. However, the present invention is not limited to this. The first sensor 29 is omittable.

(11) The first and second embodiments and each of the modified embodiments described in paragraphs (1) to (10) above may be further varied as appropriate by replacing or combining their constructions with the constructions of the other modified embodiments.

### REFERENCE SIGNS LIST

1 . . . substrate treating apparatus
10 . . . controller
11 . . . treating unit
13 . . . substrate holder
14 . . . rotation driving unit
15a . . . first nozzle (treatment liquid supplying unit)
15e . . . fifth nozzle (gas supplying unit)
16 . . . casing
20 . . . treatment liquid generating unit
21 . . . first tank
23 . . . sublimable substance supplying unit
25 . . . solvent supplying unit
27 . . . surfactant supplying unit
31 . . . liquid feeding unit
41 . . . first tank
42 . . . second tank
43 . . . third tank
44 . . . mixing unit
F1: first condition
F2: second condition
F3: third condition
F4: fourth condition
LOGPow . . . octanol-water partition coefficient of surfactant
H . . . treatment liquid
J . . . gas
K . . . solidified film
L . . . replacement liquid
Pa . . . vapor pressure of sublimable substance at room temperature
Pb . . . vapor pressure of solvent at room temperature
Pc . . . vapor pressure of surfactant at room temperature
T . . . additive amount of surfactant (ratio of volume of surfactant contained in
treatment solution to volume of solvent contained in treatment solution)
W . . . substrate
W1 . . . upper surface of substrate
R . . . pattern
W2 . . . projection
A . . . recess
S1 . . . treatment liquid generating step
S15 . . . treatment liquid supplying step
S16 . . . solidified film forming step
S17 . . . sublimation step

1. A substrate treating method for treating a substrate, the substrate treating method comprising:
a treatment liquid supplying step of supplying a treatment liquid, containing a sublimable substance, a solvent, and a surfactant, to the substrate;
a solidified film forming step of forming a solidified film containing the sublimable substance on the substrate by evaporating the solvent and the surfactant from the treatment liquid on the substrate; and
a sublimation step of sublimating the solidified film,
wherein
the surfactant has an octanol-water partition coefficient of −1 or more and 1 or less, and
vapor pressure of the surfactant at room temperature is 0.9 times or more and 3 times or less vapor pressure of the solvent at room temperature.

2. The substrate treating method according to claim 1, wherein
the vapor pressure of the solvent at room temperature is higher than the vapor pressure of the sublimable substance at room temperature.

3. The substrate treating method according to claim 1, wherein
the vapor pressure of the surfactant at room temperature is higher than the vapor pressure of the sublimable substance at room temperature.

4. The substrate treating method according to claim 1,
wherein
the sublimable substance is one selected from cyclohexanone oxime, camphor, and ε-caprolactam, and
the solvent and the surfactant correspond to one selected from features a1) to a20):
a1) the solvent is methanol, and the surfactant is acetone;
a2) the solvent is ethanol, and the surfactant is methanol;
a3) the solvent is isopropyl alcohol, and the surfactant is methanol;
a4) the solvent is isopropyl alcohol, and the surfactant is ethanol;
a5) the solvent is isopropyl alcohol, and the surfactant is tert-butanol;
a6) the solvent is tert-butanol, and the surfactant is methanol;
a7) the solvent is tert-butanol, and the surfactant is ethanol;
a8) the solvent is tert-butanol, and the surfactant is isopropyl alcohol;
a9) the solvent is 1-propanol, and the surfactant is ethanol;
a10) the solvent is 1-propanol, and the surfactant is isopropyl alcohol;
a11) the solvent is 1-propanol, and the surfactant is tert-butanol;
a12) the solvent is isobutanol, and the surfactant is 1-propanol;
a13) the solvent is 1-ethoxy-2-propanol, and the surfactant is 1-propanol;
a14) the solvent is 1-ethoxy-2-propanol, and the surfactant is isobutanol;
a15) the solvent is 1-butanol, and the surfactant is 1-propanol;
a16) the solvent is 1-butanol, and the surfactant is isobutanol;
a17) the solvent is 1-butanol, and the surfactant is 1-ethoxy-2-propanol;
a18) the solvent is propylene glycol monomethyl ether acetate, and the surfactant is isobutanol;
a19) the solvent is propylene glycol monomethyl ether acetate, and the surfactant is 1-ethoxy-2-propanol; and
a20) the solvent is propylene glycol monomethyl ether acetate, and the surfactant is 1-butanol.

5. The substrate treating method according to claim 1, wherein
the substrate has a pattern formed on a surface of the substrate.

6. A treatment liquid used to dry a substrate, the treatment liquid containing:
a sublimable substance;
a solvent; and
a surfactant,
wherein
the surfactant has an octanol-water partition coefficient of −1 or more and 1 or less, and
vapor pressure of the surfactant at room temperature is 0.9 times or more and 3 times or less vapor pressure of the solvent at room temperature.

7. The treatment liquid according to claim 6, wherein
the vapor pressure of the solvent at room temperature is higher than vapor pressure of the sublimable substance at room temperature.

8. The treatment liquid according to claim 6, wherein
the vapor pressure of the surfactant at room temperature is higher than vapor pressure of the sublimable substance at room temperature.

9. The treatment liquid according to claim 6,
wherein
the sublimable substance is one selected from cyclohexanone oxime, camphor, and ε-caprolactam, and
the solvent and the surfactant correspond to one selected from features a1) to a20):
a1) the solvent is methanol, and the surfactant is acetone;
a2) the solvent is ethanol, and the surfactant is methanol;
a3) the solvent is isopropyl alcohol, and the surfactant is methanol;
a4) the solvent is isopropyl alcohol, and the surfactant is ethanol;
a5) the solvent is isopropyl alcohol, and the surfactant is tert-butanol;
a6) the solvent is tert-butanol, and the surfactant is methanol;
a7) the solvent is tert-butanol, and the surfactant is ethanol;
a8) the solvent is tert-butanol, and the surfactant is isopropyl alcohol;
a9) the solvent is 1-propanol, and the surfactant is ethanol;
a10) the solvent is 1-propanol, and the surfactant is isopropyl alcohol;
a11) the solvent is 1-propanol, and the surfactant is tert-butanol;
a12) the solvent is isobutanol, and the surfactant is 1-propanol;
a13) the solvent is 1-ethoxy-2-propanol, and the surfactant is 1-propanol;
a14) the solvent is 1-ethoxy-2-propanol, and the surfactant is isobutanol;
a15) the solvent is 1-butanol, and the surfactant is 1-propanol;
a16) the solvent is 1-butanol, and the surfactant is isobutanol;
a17) the solvent is 1-butanol, and the surfactant is 1-ethoxy-2-propanol;
a18) the solvent is propylene glycol monomethyl ether acetate, and the surfactant is isobutanol;
a19) the solvent is propylene glycol monomethyl ether acetate, and the surfactant is 1-ethoxy-2-propanol; and
a20) the solvent is propylene glycol monomethyl ether acetate, and the surfactant is 1-butanol.

10. The treatment liquid according to claim 6,
wherein
the sublimable substance is at least one selected from cyclohexanone oxime, camphor, and ε-caprolactam, and
the solvent and the surfactant correspond to one selected from features b1) to b9):
b1) the solvent is methanol, and the surfactant is acetone;
b2) the solvent is ethanol, and the surfactant is methanol;
b3) the solvent is isopropyl alcohol, and the surfactant is at least one selected from methanol, ethanol, and tert-butanol;
b4) the solvent is tert-butanol, and the surfactant is at least one selected from methanol, ethanol, and isopropyl alcohol;
b5) the solvent is 1-propanol, and the surfactant is at least one selected from ethanol, isopropyl alcohol, and tert-butanol;
b6) the solvent is isobutanol, and the surfactant is 1-propanol;
b7) the solvent is 1-ethoxy-2-propanol, and the surfactant is at least either 1-propanol or isobutanol;
b8) the solvent is 1-butanol, and the surfactant is at least one selected from 1-propanol, isobutanol, and 1-ethoxy-2-propanol; and
b9) the solvent is propylene glycol monomethyl ether acetate, and the surfactant is at least one selected from isobutanol, 1-ethoxy-2-propanol, and 1-butanol.

11. The treatment liquid according to claim 6,
wherein
the sublimable substance is at least one selected from cyclohexanone oxime, camphor, and ε-caprolactam, and
the solvent and the surfactant correspond to one selected from features c1) to c9):
c1) the solvent is methanol, and the surfactant is acetone;
c2) the solvent is at least one selected from ethanol, isopropyl alcohol, and tert-butanol, and the surfactant is methanol;
c3) the solvent is at least one selected from isopropyl alcohol, tert-butanol, and 1-propanol, and the surfactant is ethanol;
c4) the solvent is at least either isopropyl alcohol or 1-propanol, and the surfactant is tert-butanol;
c5) the solvent is at least either tert-butanol or 1-propanol, and the surfactant is isopropyl alcohol;
c6) the solvent is at least one selected from isobutanol, 1-ethoxy-2-propanol, and 1-butanol, and the surfactant is 1-propanol;
c7) the solvent is at least one selected from 1-ethoxy-2-propanol, 1-butanol, and propylene glycol monomethyl ether acetate, and the surfactant is isobutanol;
c8) the solvent is at least either 1-butanol or propylene glycol monomethyl ether acetate, and the surfactant is 1-ethoxy-2-propanol; and
c9) the solvent is propylene glycol monomethyl ether acetate, and the surfactant is 1-butanol.

12. The treatment liquid according to claim 6, wherein
a volume of the sublimable substance contained in the treatment liquid is smaller than a volume of the solvent contained in the treatment liquid.

13. The treatment liquid according to claim 6, wherein
a volume of the sublimable substance contained in the treatment liquid is 1% or more and 10% or less of a volume of the solvent contained in the treatment liquid.

14. The treatment liquid according to claim 6, wherein
a volume of the surfactant contained in the treatment liquid is smaller than a volume of the solvent contained in the treatment liquid.

15. The treatment liquid according to claim 6, wherein
a volume of the surfactant contained in the treatment liquid is 0.01% or more and 10% or less of a volume of the solvent contained in the treatment liquid.
